(19) United States
(12) Patent Application Publication
(10) Pub. No.: US 2009/0152595 A1
(43) Pub. Date: Jun. 18, 2009

(54) SEMICONDUCTOR DEVICES AND METHOD OF TESTING SAME

(75) Inventors: Toru Kaga, Tokyo (JP); Yoshihiko Naito, Tokyo (JP); Masatoshi Tsuneoka, Tokyo (JP); Kenji Terao, Tokyo (JP); Nobuharu Noji, Tokyo (JP); Ryo Tajima, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EBARA CORPORATION, Tokyo (JP)

(21) Appl. No.: 12/066,470

(22) PCT Filed: Sep. 8, 2006
(86) PCT No.: PCT/JP2006/318321

§ 371 Date: Mar. 11, 2008

(30) Foreign Application Priority Data
Sep. 13, 2005 (JP) 2005-264683
Oct. 3, 2005 (JP) 2005-290247
Apr. 28, 2006 (JP) 2006-125967
Apr. 28, 2006 (JP) 2006-126146

(51) Int. Cl. H01L 23/522; G01R 31/302

(52) U.S. Cl. 257/208; 257/786; 324/750; 257/E23.012; 257/E21.575; 257/E21.521

(57) ABSTRACT

There are provided a semiconductor device having a pattern which allows electric failures to be sensitively detected at high speeds, and a method of testing the same. In one embodiment, the semiconductor device comprises a pair of row wires including a plurality of first wires arranged in a first layer at predetermined intervals in a row direction, where the first wires have ends connected to second wires arranged in a second layer at a predetermined intervals through vias, and the first wire and second wire are at the same potential. In the pair of row wires, a first wire positioned at a right end of one row wire is connected to a first conductor, and a first wire positioned at a left end in the other row wire is connected to a second conductor. By sequentially scanning the first conductor and second conductor using an electron beam, a change in the amount of emitted secondary electrons due to a difference in potential between these conductors is detected to detect electric anomalies.

### TECHNICAL FIELD

The present invention relates to semiconductor devices and methods of testing the same. Particularly, the present invention relates to a variety of Si LSI's such as a dynamic random access memory (DRAM), a flash memory, logic LSI's and the like, as well as structures for the semiconductors and methods of testing the same, which are capable of highly sensitively detecting, in a short time, defects such as a wire short failure, a wire open failure, a self aligned contact short failure and the like which occur due to defective dimensions of wire widths and contact diameters in those Si LSI's.

### BACKGROUND ART

A variety of proposals have been conventionally made for detecting electric failures which are found in wires of semiconductor devices. An example of them is a voltage contrast method described in Laid-open Japanese Patent applications Nos. 11-27066 and 2000-223540, which will be now described with reference to FIG. 1. In FIG. 1, a semiconductor device has a structure that comprises a plurality of wires 401a-401k and 402a-402k, which extend in an X-direction on a substrate S, arranged in parallel with one another in a Y-direction. As illustrated in the figure, among these alternating wires, a first set of wires 401a-401k and second set of wires 402a-402k are disposed at different positions in the X-direction. Specifically, the second set of wires 402a-402k protrude downward in the figure, and the protruding ends are connected together to a single powering wire 403 which is applied with a predetermined potential. On the other hand, the first set of wires 401a-401k are respectively at a floating potential.

When the semiconductor device in such a structure and an electron beam are relatively moved in the Y-direction while the semiconductor device is irradiated with the electron beam, the potential of the second set of wires 402a-402k is fixed at the previously applied predetermined potential and does not change when no electric failure occurs. On the other hand, the potential of the first set of wires 401a-401k in a floating state varies by a portion corresponding to the “amount of electrons generated by the irradiation” minus the “amount of emitted secondary electrons,” so that the amount of secondary electrons emitted from the first set of wires 401a-401k differs from the amount of electrons emitted from the second set of wires 402a-402k. Accordingly, by detecting a change (i.e., a difference) in the amount of emitted secondary electrons, wires at the floating potential can be separated from wires at the fixed potential for extraction. This is called the voltage contrast method (VC method).

Assuming now that one wire within the first set of wires at the floating potential, for example, a wire 401d shorts with a wire 402c at the fixed potential, adjacent thereto, the potential at the wire 401d, which has been so far at the floating potential, changes to the fixed potential. Therefore, when scanning with an electron beam as mentioned above, the amount of secondary electrons emitted from the wire 401d is the same as the amount of secondary electrons emitted from the wires 402c, 402d at the fixed potential, which sandwich the wire 401d. In this way, the wire 401d can be separated from the remaining wires at the floating potential for extraction, thus making it possible to detect which wire has shorted with an adjacent wire.

As will be understood from the foregoing description, the voltage contrast method is effective for detecting the occurrence of shorts for the semiconductor having the structure illustrated in FIG. 1. However, the detection of the occurrence of a short requires the ability to detect a portion in which the amount of emitted secondary electrons has changed due to the short with an adjacent wire at the fixed potential from among alternating wires at the floating potential, i.e., a detection resolution which enables discrimination of a change in the amount of secondary electrons emitted from adjacent wires. Specifically, when an image of emitted secondary electrons is displayed, a normal semiconductor device would present higher voltage contrast portions and lower voltage contrast portions arranged in an alternating pattern, so that a display device will display repetitions of alternating light portions and dark portions, such as light, dark, light, dark, light, dark, . . . . On the other hand, if a short has occurred in a part, the regular light/dark repetitions will break, resulting in a display of irregular changes, for example, light, dark, dark, dark, light, dark, . . . , or the like. Therefore, for effectively practicing the voltage contrast method, a detection resolution is required in such a degree that at least a change from light to dark or from dark to light can be recognized.

However, the pitch of wires in semiconductor devices is increasingly smaller year by year, so that the detection resolution cannot but be increasingly smaller in association therewith. As a result, a problem arises that electric failures are detected at speeds which are increasingly lower year by year.

FIG. 2 illustrates another approach for detecting an electric defect. This figure illustrates the structure of a TEG (Test Element Group) area 404 in which a plurality of contacts 405 for connecting between a first layer and a second layer are two-dimensionally arranged on a periodic basis. When a portion 406 of a large number of these contacts 406 suffers from a conduction failure, this may be detected by irradiating all the contacts 405 with an electron beam EB which is narrowed down to be fine enough to detect one contact, and sequentially scanning them. If the defectively conducting contact 406 is found halfway in this scan, a difference in surface potential is produced due to the conduction failure at this contact 406, so that the amount of secondary electrons emitted from the contact differs from the amount of secondary electrons emitted from a normal contact. Accordingly, the defectively conducting contact is detected by detecting the difference in the amount of emitted secondary electrons.

However, the method which irradiates contacts with an electron beam EB to sequentially test the contacts one by one in this manner performs the scan using the fine electron beam EB, thus giving rise to a problem that an extremely long time is required to scan the overall surface of semiconductor.

A method proposed to improve this problem is the structure illustrated in FIGS. 3(A), 3(B), 3(C). In the structure illustrated in these figures, a plurality of vias 412 are two-dimensionally arranged on a periodic basis in a TEG area 411, two adjacent vias are connected in between by a wire in an overlying layer to form a set, and respective vias in each set are connected to an adjacent set of vias through a wire in an underlying layer. Specifically, as illustrated in FIGS. 3(B) and 3(C), adjacent vias 412₁, 412₂ forms one set, and are connected in between by a wire 413 in the overlying layer. In FIG. 3(A), part of the wire 413 in the overlying layer, which connects between the bias, is indicated by a bold black line. One via 412₁ is connected to a nearer via 412₃ of vias in an adjacent set on the left side through a via 414 in the underlying layer, while the other via 412₂ is connected to a nearer via 412₄ of adjacent vias on the right side through a wire 415 in the underlying layer. The via 412₃ is connected to a wire 416 at a left end, and the via 412₄ to a wire 417 at a right end, respectively. A wire 418 in the underlying layer at a left end is connected to an Si substrate through a contact 419 and remains at a ground potential.

In the semiconductor structure illustrated in FIGS. 3(A), 3(B), 3(C), a defectively conducting via (portion surrounded by a circle), if any, exerts the influence of the conduction failure on all wires electrically connected to this via. For example, in the structure where vias are connected by wires in a row direction (in a left-to-right direction, as viewed from the front of the drawing) as illustrated in FIGS. 3(B), 3(C), if one via suffers from a conduction failure, a secondary electron emission rate changes in all the vias on the left side thereof (or all on the right side) and wires connected to them. Consequently, wires 416, 413 connected to a wire 418 at the ground potential are at the ground potential, whereas a wire 417 on the right side of the location of the defectively conducting via is at an open potential. For this reason, if a scan is performed using an electron beam EB in a direction across the overlying wire 413, the potential on wires in a row which includes the defectively conducting via differs from the potential on normal wires. Accordingly, since the secondary electron emission rate also differs from that on other wires, a row including an unwanted via can be detected by revealing such a change in the secondary electron emission rate.

As described above, in the structure illustrated in FIGS. 3(A), 3(B), 3(C), since an area of a portion in which the secondary electron emission rate should be detected is larger than that of FIG. 3, a wider electron beam can be used for detecting a change in the secondary electron emission rate than the electron beam used in FIG. 3, thus making it possible to reduce a detection time for the overall semiconductor surface. However, though the conventional testing method described in connection with FIGS. 3(A), 3(B), 3(C) can produce predetermined effects in improving the detection sensitivity and increasing the testing speed, this method cannot sufficiently support the trend of increasingly larger areas of wafers, advanced in the Si LSI manufacturing, and miniaturization every two to three years. Therefore, it is essential to further improve the testing sensitivity and testing speed.

The present invention has been proposed to solve the problems mentioned above, and it is an object of the present invention to provide a semiconductor device which has a pattern that enables highly sensitive and high-speed detection of electric failures, and a method of testing the same. It is another object of the present invention to provide a semiconductor device which has a structure for improving a testing sensitivity and a testing speed, where conductors for detecting a conduction failure are separately disposed in a left and a right area to relieve a wiring pitch and increase a width, and a method of testing the semiconductor device. It is a further object of the present invention to provide a semiconductor device which has a structure that enables not only a detection as to the presence or absence of short-circuit failure, but also a variety of tests for a dimensional margin for short-circuit resistance, a dimensional margin for line break resistance, a margin for conduction failure resistance, and the like, and a method of testing the same.

### DISCLOSURE OF THE INVENTION

The respective objects are achieved by the present invention to make technical advances.

In one aspect, the present invention provides a semiconductor device comprising a pair of row wires including a plurality of first wires arranged in a first layer at predetermined intervals in a row direction, where the first wires have ends connected to second wires arranged in a second layer at predetermined intervals through vias, and the first wires are at the same potential as the second wires. The semiconductor device comprises:

a first conductor connected to the first wire positioned at a first end in one row wire of the pair of row wires in the row direction, and a second conductor connected to the first wire positioned at a second end in the other row wire in the row direction.

In another aspect, the present invention provides a semiconductor device comprising a pair of row wires arranged in a first layer to be elongated in a row direction, and a column wire formed in a column direction so as to overlap an end of one of the pair of row wires, wherein:

in the pair of row wires,

one row wire has a first end in the row direction connected to a first conductor, and a second end connected to the column wire through a via to be set to a first potential; and

the other row wire has a second end in the row direction connected to a second conductor, and the row wire is set to a second potential.

Preferably, the first conductor and the second conductor have a width in the column direction equal to or more than twice and equal to or less than three times as wide as a width of the first wire in the column direction.

Preferably, the first conductor is scanned using an electron beam, and then the second conductor is scanned using the electron beam to detect a change in the amount of emitted secondary electron, resulting from a difference in potential between these conductors, to detect an electric failure.

Preferably, the electric failure is a short or an open.

In another aspect, the present invention provides a semiconductor device which comprises:

a first pair of gate electrodes arranged in a first layer and elongated in a row electrode;

a second pair of gate electrodes arranged in the first layer, and elongated in the row direction;

first self-aligned contacts arranged between the gate electrodes of the first pair of gate electrodes at predetermined intervals in the row direction;

second self-aligned contacts arranged between the gate electrodes of the second pair of gate electrodes at predetermined intervals in the row direction;

a first row wire arranged in a second layer and electrically connected to the first self-aligned contact;

a second row wire arranged in the second layer, and electrically connected to the second self-aligned contact;

means arranged in the second layer at a first end in the row direction for setting the first row wire and the second row wire to a first potential;

a first conductor arranged in the second layer, and connected to the first pair of gate electrodes at a second end in the row direction; and

a second conductor arranged in the second layer, and connected to the second pair of gate electrodes at the second end in the row direction,

wherein the first conductor and the second conductor are set to a second potential different from the first potential.

Preferably, the first conductor and the second conductor have a width in the column direction corresponding to the first pair of gate electrodes and the second pair of gate electrodes.

Preferably, the first layer comprises an active area which has a diffusion layer connected to each of the first self-aligned contact and the second self-aligned contact.

In a further aspect, the present invention provides a semiconductor device which comprises:

a first interdigital gate electrode arranged in a first layer and elongated in a row direction;

a second interdigital gate electrode arranged in the first layer, and elongated in the row direction;

a first self-aligned contact arranged between digits of the first gate electrode;

a second self-aligned contact arranged between digits of the second gate electrode;

a first row wire arranged in a second layer, and electrically connected to the first self-aligned contact;

a second row electrode arranged in the second layer, and electrically connected to the second self-aligned contact;

means arranged in the second layer at a first end in the row direction for setting the first row wire and the second row wire to a first potential;

a first conductor arranged in the second layer at a second end in the row electrode, and electrically connected to the first row wire; and

a second conductor arranged in the second layer at the second end, and electrically connected to the second row wire,

wherein the first conductor and the second conductor are set to a second potential different from the first potential.

Preferably, the first conductor and the second conductor have a width in the column direction corresponding to the first gate electrode and the second gate electrode.

Preferably, the first layer comprises a linear or intermittent active area in the row direction having a diffusion layer connected to each of the first self-aligned contact and the second self-aligned contact.

In a yet another aspect, the present invention provides a semiconductor device which comprises:

a first pair of gate electrodes arranged in a first layer, and elongated in a row direction;

a second pair of gate electrodes arranged in the first layer, and elongated in the row direction;

a series of first bit contacts arranged between the first pair of gate electrodes at predetermined intervals in the row direction;

a series of second bit contacts arranged between the second pair of gate electrodes at predetermined intervals in the row direction;

a series of first active areas formed in the first layer, and having, on a surface, a diffusion layer connected to two adjacent bit contacts of the series of first bit contacts;

a series of second active areas formed in the first layer, and having, on a surface, a diffusion layer connected to two adjacent bit contacts of the series of second bit contacts;

a series of first wires for electrically connecting two adjacent bit contacts of the series of first bit contacts;

a series of second wires for electrically connecting between two adjacent bit contacts of the series of second bit contacts;

a first conductor electrically connected to a bit contact positioned at a first end in the row direction of the series of first bit contacts;

a second conductor electrically connected to a bit contact positioned at a first end in the row direction of the series of second bit contacts;

a third conductor electrically connected to the second pair of gate electrodes at the second ends of the first pair of gate electrodes;

a fourth conductor electrically connected to the second pair of gate electrodes at the second ends of the second pair of gate electrodes in the row direction; and

means arranged in the second layer for setting the series of first wires, the series of second wires, the first conductor, and the second conductor to a first potential,

wherein the third conductor and the fourth conductor are set to a second potential different from the first potential.

Preferably, the first conductor, the second conductor, the third conductor, and the fourth conductor have a width in the column direction corresponding to the first pair of gate electrodes and the second pair of gate electrodes.

Preferably, the first conductor and the second conductor are scanned using an electron beam to detect a change in the amount of emitted second electrons, resulting from a difference in potential on these conductors, to detect an electric anomaly.

In another aspect, the present invention provides a semiconductor device characterized by comprising a basic wiring pattern including:

a first inverted C-shaped wire having a pair of parallel interdigital conductors; and

a second inverted C-shaped wire having a pair of parallel interdigital conductors and arranged interdigitally with respect to the first wire,

wherein the first wire and the second wire are set to electrically different potentials such that a short can be detected between the wires.

In another aspect, the present invention provides a semiconductor device which comprises a basic wiring pattern including:

a first inverted C-shaped wire having parallel interdigital conductors; and

a second linear wire arranged between the parallel interdigital conductors,

wherein the first wire and the second wire are set to electrically different potentials, such that a short can be detected between the wires.

In another aspect, the present invention provides a semiconductor device which comprises a basic wiring pattern including:

a first interdigital wire having a plurality of parallel interdigital conductors; and

a second wire having a plurality of parallel interdigital conductor, and interdigitally arranged with respect to the first wire,

wherein the first wire and the second wire are set to electrically different potentials, such that a short can be detected between the wires.

Preferably, the first wire is electrically grounded, and the second wire is at a floating potential.

In a further aspect, the present invention provides a semiconductor device which comprises a basic wiring pattern including an inverted C-shaped wire having parallel interdigital conductors, wherein a predetermined potential is applied to an end of one of the interdigital conductors, such that an opened wire can be detected.

In a yet another aspect, the present invention provides a semiconductor device which comprises a basic wiring pattern including a zig-zag shaped wire, wherein the wire is set to a predetermined potential, such that an opened wire can be detected.

In a yet further aspect, the present invention provides a semiconductor device which comprises a basic wiring pattern including:

a first zig-zag wire having a plurality of parallel conductors; and

a second interdigital wire interdigitally arranged with respect to the first wire, the second wire having interdigital conductors positioned between opposing conductors of the first wire,

wherein the first wire and the second wire are set to electrically different potentials, such that a short between the wires and an opened wire can be detected.

In a yet another aspect, the present invention provides a semiconductor device which comprises a basic wiring pattern including:

a first interdigital wire having a plurality of parallel interdigital conductors;

a second zig-zag wire having a plurality of parallel conductors, wherein at least a pair of the conductors are positioned between opposing interdigital conductors of the first wire; and

a third interdigital wire having a plurality of parallel interdigital conductors extending in a direction opposite to the interdigital conductors of the first wire, and positioned between the opposing conductors of the second wire,

wherein the second wire is set to a predetermined potential, and the first wire and the third wire are set to a potential different from the predetermined potential, such that a short between the wires, and an opened wire can be detected.

In a yet further aspect, the present invention provides a semiconductor device which comprises a basic wiring pattern including:

a first interdigital wire having a plurality of parallel interdigital conductors;

a second wire for connecting at least two adjacent conductors of the plurality of linear conductors arranged alternately with the interdigital conductors,

wherein the first wire is set to a predetermined potential, and the second wire is set to a potential different from the predetermined potential, such that a short can be detected between the wires.

In a further aspect, the present invention provides a semiconductor device which comprises a basic wiring pattern including:

a first zig-zag wire having a plurality of parallel conductors;

a second conductor having a plurality of inverted C-shaped conductors, wherein the respective inverted C-shaped conductors area arranged to sandwich a pair of the opposing conductors of the first wire from both sides with respect to a lengthwise direction of the first wire,

wherein the first wire is set to a predetermined potential, and the second wire is set to a potential different from the predetermined potential, such that a short between the wires and an opened wire can be detected.

In a yet another aspect, the present invention provides a semiconductor device which comprises a basic wiring pattern having one or more via chain including two adjacent conductors formed in a first layer, opposing ends interconnected through a contact and a conductor formed in a second layer, wherein the via chain is set to a predetermined potential, such that a conduction failure of a via can be detected.

Preferably, the semiconductor device comprises a basic wiring pattern which has the via chains arranged to form a zig-zag line.

Preferably, a plurality of the via chains are arranged in a line, and at least one reference row is disposed adjacent to the wiring pattern.

Preferably, the basic wiring pattern has a wiring pattern arranged in n rows and m columns.

Preferably, a minimum pixel size of a tester for use in testing the semiconductor device is set to a wiring pitch.

Preferably, a maximum pixel size for a tester for use in testing the semiconductor device according to any of claims 15 to 28 is set to the size of a basic wiring pattern in a scanning direction of a electron beam for the test, or to the size of the same pattern which appears in the basic wiring pattern in the scanning direction.

In one aspect, the present invention provides a semiconductor device which comprises a group of TEG's including two or more TEG's each having a wire at a ground potential and a wire at a floating potential, wherein:

the wires have the same line width and spacing in each of the TEG's, and one of the line width and spacing of the wires is different among different ones of the TEG's.

In another aspect, the present invention provides a semiconductor device which comprises a group of TEG's including two or more TEG's each having at least two wires at a predetermined potential, wherein:

the wires have the same line width and spacing in each of the TEG's, and one of the line width and spacing of the wires is different among different ones of the TEG's.

In another aspect, the present invention provides a semiconductor device having a first layer formed on a first side of an insulating layer, and a second layer formed on a second side opposite to the first side, the semiconductor device comprising:

a group of TEG's having two or more TEG's, each including:

a first row wire having a plurality of wires formed in the first layer and arranged at predetermined intervals in a row direction;

a second row wire having a plurality of wires formed in the second layer so as to overlap the first row wire and include adjacent ends of the plurality of wires; and

conductors such as vias and a contact for electrically connecting the wires in the first row wire to the wires in the second row wire,

wherein the conductors are different in diameter or interval among different TEG's.

Preferably, the semiconductor device is tested by irradiating each of the TEG's with an electron beam to emit secondary electrons from the TEG's, and detecting the presence or absence of a wire failure site in the TEG's based on the amount of the emitted secondary electrons in accordance with a voltage contrast method.

Preferably, the semiconductor device is tested by executing the step of previously storing a wiring pitch of each of the TEG's, or automatically detecting a wiring pitch of each of the TEG's, and continuously detecting wire failure sites using the previously stored wiring pitch or the automatically detected wiring pitch.

Preferably, the semiconductor device is tested by testing a plurality of groups of the TEG's on a wafer, and finding a relationship between design dimensions and a yield rate of each TEG for each of the groups of TEG's.

Preferably, the semiconductor device is determined to be defective when the yield rate is smaller than a predetermined value.

Preferably, a representative TEG is selected from the group of TEG's, and the yield rate is measured for the representative TEG.

Preferably, each dimension of the TEG has a value corresponding to the sum of or the difference between a design dimension and an allowable margin.

In one aspect, the present invention provides a semiconductor device which comprises a wiring pattern including at least one TEG which has a plurality of wires arranged symmetrically to and parallel with an axis such that their ends oppose each other, wherein the other end of every other wire is grounded, and the remaining wires are at a floating potential in the plurality of wires.

In another aspect, the present invention provides a semiconductor device which comprises a wiring pattern including at least one TEG which has a plurality of wires arranged symmetrically to and parallel with an axis such that their ends oppose each other, wherein the other ends of the plurality of wires are connected to a ground electrode.

Preferably, the plurality of wires are arranged in a first wiring layer, the ground electrode is arranged in a second wiring layer different from the first wiring layer, and the plurality of wires and the ground electrode are connected through vias.

Preferably, the semiconductor device further comprises a wire disposed in an area having a predetermined width centered at the axis, and set at a the ground potential or the floating potential.

Preferably, the semiconductor device comprises a wiring pattern which has a plurality of the TEG's arranged in a predetermined direction.

Preferably, a multiple of two or a multiple of two's power of the TEG's are arranged in the predetermined direction.

Preferably, a plurality of the TEG's are different in design parameters such as a line width, a distance between lines, and the like from one another, and a plurality of the TEG's are arranged in an order in which line break failures occur less frequently with respect to an electron beam scanning direction during a test in accordance with voltage contrast.

Preferably, the plurality of TEG's are arranged across a plurality of wiring layers, wherein TEG's arranged in the same wiring layer are continuously arranged with respect to the electron beam scanning direction during the test in accordance with the voltage contrast.

Preferably, TEG's which less frequently suffer from line break failure are arranged on one side, or on the other side, or on both sides of the TEG's arranged in the same wiring layer, with respect to the electron beam scanning direction during the test in accordance with the voltage contrast.

Preferably, when the TEG's arranged in the same wiring layer include a TEG for short-circuit failure detection and a TEG for line break failure detection, the TEG for short-circuit failure detection is arranged on an upstream side with respect to the electron beam scanning direction during the test in accordance with the voltage contrast.

Preferably, the TEG is disposed in a scribe area in a direction parallel or perpendicular to the axis within a field exposed to the electron beam.

Preferably, the semiconductor device further comprises a ground wire surrounding the periphery of the wiring pattern.

Preferably, the semiconductor device is tested by irradiating an electron beam to an area having a predetermined width and including ends of the plurality of wires opposite to the axis, and detecting a defective locations based on a voltage contrast signal corresponding to the amount of secondary electrons emitted from the area.

Preferably, the semiconductor device is scanned using the electron beam in a direction parallel with the axis while sequentially shifting the position, and defective locations is continuously detected based on the voltage contrast signal corresponding to the amount of secondary electrons emitted in response to the irradiation of the electron beam.

Preferably, the electron beam is simultaneously irradiated the electron beam to a plurality of areas positioned at predetermined intervals in a direction perpendicular to the axis to continuously detect defective locations.

Preferably, the width of the TEG in a direction perpendicular to the axis is divided by the width of the electron beam in a direction perpendicular to the axis to result in a multiple of two or a two's power.

Preferably, the semiconductor device is scanned in the direction perpendicular to the axis using the electron beam having a first width to detect the TEG in which a failure exists, and

then the TEG in which a failure has been detected is detected in the direction perpendicular to the axis using the electron beam having a second width smaller than the first width.

Preferably, the width of the TEG in the direction perpendicular to the axis is divided by the first width to result in a multiple of two or a two's power, and the first width is divided by the second width to result in an integer, a multiple of two, or a two's power.

Preferably, the scan is performed using the electron beam without scanning outside of an area in which the wiring pattern is formed.

The above and other objects and features of the present invention will become more apparent from the following detailed description, when read with reference to the accompanying drawings.

### BRIEF DESCRIPTION OF THE DRAWINGS

FIG. 1 is a diagram illustrating a wiring pattern in a conventional semiconductor device;

FIG. 2 is a diagram for describing a conventional approach for detecting an electric failure;

FIG. 3 is a diagram for describing another conventional approach for detecting an electric failure, where (A) and (B) are diagrams illustrating the structure of a semiconductor device, and (C) is a cross-sectional view taken along a line X-X in (B);

FIG. 4 is a diagram generally illustrating a first embodiment of a semiconductor device according to the present invention;

FIGS. 5(A) and 5(B) are diagrams generally illustrating a second embodiment of a semiconductor device according to the present invention;

FIG. 6 is a diagram generally illustrating the structure of a bit contact and a gate electrode of a conventional DRAM;

FIGS. 7(A) and 7(B) are diagrams generally illustrating a third embodiment of a semiconductor device according to the present invention;

FIGS. 8(A)-8(C) are diagrams generally illustrating a fourth embodiment of a semiconductor device according to the present invention;

FIGS. 9(A) and 9(B) are diagrams generally illustrating a fifth embodiment of a semiconductor device according to the present invention;

FIGS. 10(A) and 10(B) are diagrams generally illustrating a sixth embodiment of a semiconductor device according to the present invention;

FIG. 11 is a diagram generally illustrating a basic wiring pattern in the first embodiment of the semiconductor device according to the present invention;

FIGS. 12(A) and 12(B) are diagram for describing the operation of the first embodiment;

FIG. 13 is a diagram of the basic wiring patterns in FIG. 11 which are arranged in a 2×2 matrix;

FIG. 14 is a diagram of the basic wiring patterns in FIG. 11 which are arranged in a 2×2 matrix;

FIG. 15 is a diagram for describing a detection resolution for detecting the basic pattern in FIG. 11;

FIG. 16 is a diagram for describing a detection resolution for detecting the basic pattern in FIG. 11;

FIG. 17 is a diagram generally illustrating a basic wiring pattern in the second embodiment of the semiconductor device according to the present invention;

FIGS. 18(A) and 18(B) are diagrams generally illustrating a basic wiring pattern in the third embodiment of the semiconductor device according to the present invention, and FIG. 18(C) is a diagram for describing the operation when a wire open failure is found;

FIG. 19(A) is a diagram generally illustrating a basic wiring pattern in the fourth embodiment of the semiconductor device according to the present invention, and FIGS. 19(B) and 19(C) are diagrams for describing the operations when a wire short and open failure are found;

FIG. 20 is a diagram generally illustrating a basic wiring pattern in the fifth embodiment of the semiconductor device according to the present invention;

FIG. 21 is a diagram generally illustrating a basic wiring pattern in the sixth embodiment of the semiconductor device according to the present invention;

FIG. 22 is a diagram for describing the operation of the six embodiment illustrated in FIG. 21;

FIG. 23 is a diagram generally illustrating a basic wiring pattern in a seventh embodiment of a semiconductor device according to the present invention;

FIG. 24 is a diagram for describing the operation when a short occurs in the seventh embodiment illustrated in FIG. 23;

FIG. 25 is a diagram for describing the operation when an open occurs in the seventh embodiment illustrated in FIG. 23;

FIG. 26(A) is a diagram generally illustrating a basic wiring pattern in an eighth embodiment of a semiconductor device according to the present invention, and FIG. 26(B) is a diagram for describing the operation when a via open occurs;

FIG. 27 is a diagram illustrating one exemplary modification to the eighth embodiment illustrated in FIG. 26;

FIG. 28 is a diagram illustrating another exemplary modification to the eighth embodiment illustrated in FIG. 26;

FIG. 29 is a diagram generally illustrating a basic wiring pattern in a ninth embodiment of a semiconductor device according to the present invention;

FIG. 30 is a diagram illustrating one exemplary modification to the ninth embodiment illustrated in FIG. 29;

FIGS. 31(A-1)-31(A-3) generally illustrate the structures of wire short detection TEG's for measuring a dimensional margin for short-circuit resistance according to the present invention, respectively, and 31(B) is a cross-sectional view of one TEG;

FIG. 32(A) illustrates an image which is generated when there is no short-circuited location in a TEG, and 32(B) illustrates an image which is generated when an electrically short-circuited location exists in a TEG;

FIGS. 33(A-1)-(A-3) are diagrams generally illustrating the structure of a wire break detection TEG for measuring a wire break margin according to the present invention;

FIG. 34(A) illustrates an image generated from a normal TEG, and 34(B) illustrates an image when a line break exists at a location in a TEG;

FIGS. 35(A-1), 35(A-2) and 35(A-3) generally illustrate the structure of a TEG for measuring a via or contact conduction failure margin according to the present invention;

FIG. 36 is a graph showing the relationship between a change in line width of wires, taken from TEG's having similar functions to the TEG's illustrated in FIGS. 33(A-1)-33(A-3), and a yield rate of each TEG;

FIG. 37 is a graph which records variations in the yield rate of a representative TEG together with the date or lot number;

FIG. 38 is a diagram generally illustrating the first embodiment of the semiconductor device according to the present invention, which comprises a TEG having two types of wires at different potentials, arranged in an alternating pattern and in bilateral symmetry;

FIG. 39 is a diagram generally illustrating the second embodiment of the semiconductor device according to the present invention, which comprises a TEG in which the TEG's illustrated in FIG. 2 are laid out in a large scale;

FIG. 40 is a diagram generally illustrating the third embodiment of the semiconductor device according to the present invention, which comprises three TEG areas each having two pairs of wires that oppose each other;

FIG. 41 is a diagram generally illustrating the fourth embodiment of the semiconductor device according to the present invention, which is developed from the TEG illustrated in FIG. 40;

FIG. 42 is a diagram generally illustrating the fifth embodiment of the semiconductor device according to the present invention, which comprises a dummy TEG;

FIG. 43 is a diagram generally illustrating the fifth embodiment of the semiconductor device according to the present invention;

FIG. 44 is a diagram generally illustrating the fifth embodiment of the semiconductor device according to the present invention;

FIG. 45 is a diagram generally illustrating the fifth embodiment of the semiconductor device according to the present invention; and

FIG. 46 is a diagram generally illustrating the fifth embodiment of the semiconductor device according to the present invention.

### BEST MODE FOR CARRYING OUT THE INVENTION

In the following, embodiments of semiconductor devices according to the present invention will be described in detail with reference to the drawings. Assume that throughout the drawings, the same or similar components are designated by the same reference numerals. In the following, a first layer and a second layer represent different layers in a semiconductor device, wherein, the first layer indicates an upper layer, and the second layer indicates a lower layer, by way of example. Also, when left or right is referred to, this means the left or right direction as viewed from the front of the drawing.

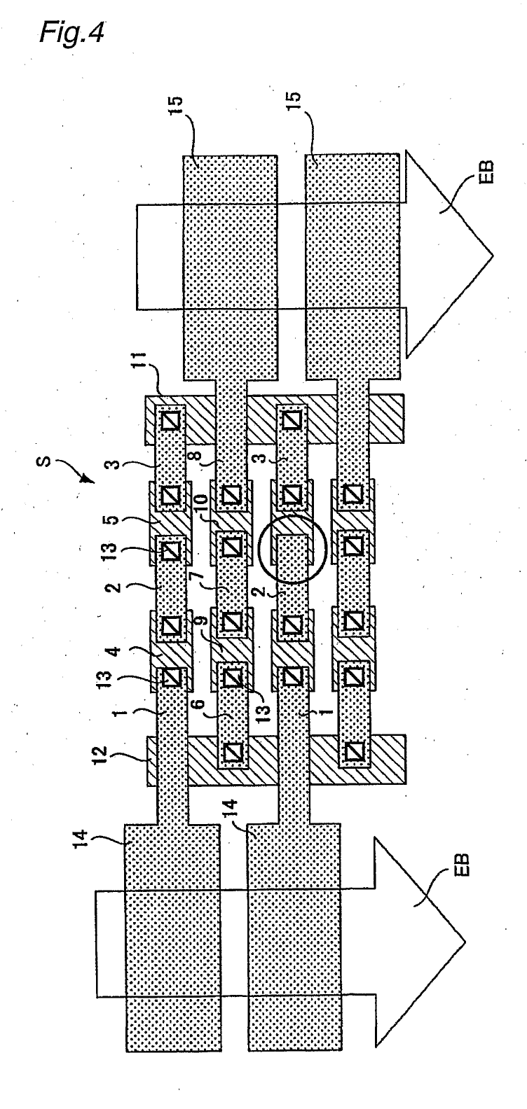

FIG. 4 illustrates a first embodiment of a semiconductor device according to the present invention. In FIG. 4, a semiconductor device S has a semiconductor structure which comprises multiple basic structures, each including a via chain for connecting an upper layer wire and a lower layer wire through a via, which are two-dimensionally arranged on a periodic basis. Specifically, the basic structure of the semiconductor device S includes the following components, and FIG. 4 illustrates two basic structures:

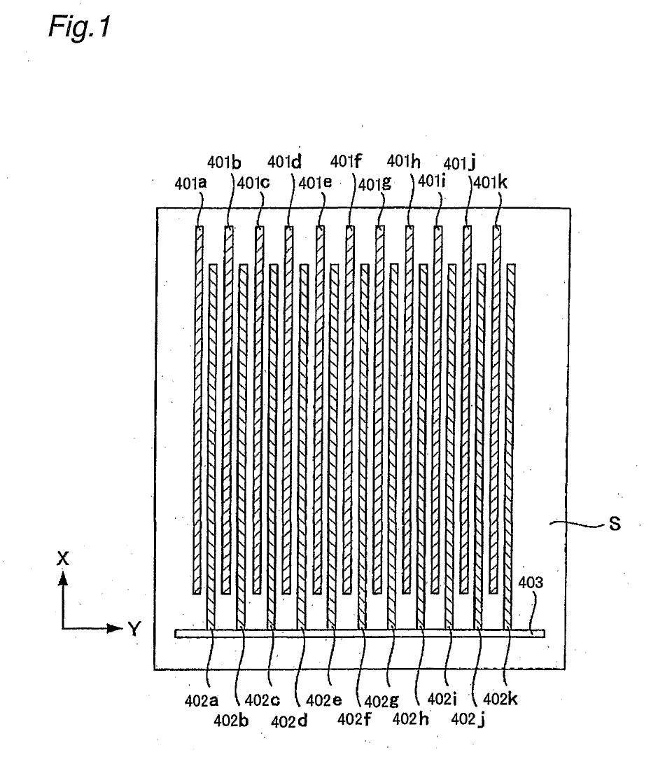

(1) a first row wire which has a plurality of wires 1, 2, 3 arranged at predetermined intervals in a row direction (in a left-to-right direction in FIG. 1) in a first layer;

(2) wires 4, 5 formed in a lower layer at positions at which they can connect adjacent ends of the wires 1, 2, 3 in the first layer;

(3) a second row wire which has a plurality of wires 6, 7, 8 arranged at predetermined intervals in the row direction, disposed in the first layer in parallel with the first row wire;

(4) wires 9, 10 in a second wire formed at positions at which they can connect adjacent ends of the wires 6, 7, 8 in the first layer;

(5) ground electrodes 11, 12 which are elongated in a column direction, formed in the second layer such that they overlap both ends of the first row wire and second row wire;

(6) vias 13 for connecting between ends of the wires 1, 2, 3, 6, 7, 8 in the first layer and ends of the wires 4, 5, 9, 10 in the second layer;

(7) a conductor 14 having a width wider than the wires 1, 2, 3, and connected to the wire 1, located at the left end, of the first row wire; and

(8) a conductor 15 having a width wider than the row wires 6, 7, 8, and connected to the wire 8, located at the right end, of the second row wire.

In this way, in the first embodiment, since a wiring pitch of the conductors 14, 15 are one-half of a wiring pitch of row wires in the via chain, the conductors 14, 15 can be formed wider than the row wires in the column direction. Therefore, when the same design rule of wires in the via chain can be used as a design rule for the conductors 14, 15, the conductors 14, 15 can be formed to have a wire width three times as wide as a minimum wire width and a minimum space. As such, when the conductors 14, are scanned using an electron beam EB, the amount of secondary electrons emitted from one conductor increases approximately by a factor of three, as compared with a test which is conducted by irradiating fine wires with an electron beam in a conventional manner, thus largely improving the sensitivity.

In this embodiment, if a conduction failure occurs in a via at a location surrounded by a circle in the figure, the wires 1, 2 and conductor 14 on the left side from the ground electrode 11 transitions to a floating potential with reference to that via. Thus, the conductor at a ground potential differs in the secondary electron emission rate from the conductor at the floating potential, so that as the conductors 14 are scanned using an electron beam EB, a conductor connected to a row wire including the defectively conducting via presents an amount of emitted secondary electrons different from the remaining conductors. On the other hand, the conductors 15 on the opposite side are at the ground potential, so that even if the conductors 15 are scanned using the electron beam EB, no variations are recognized in the secondary electron emission rate of the conductors 15. In this way, by examining the amount of secondary electrons emitted from the conductors, it is possible to identify a row wire which includes a defectively conducting via.

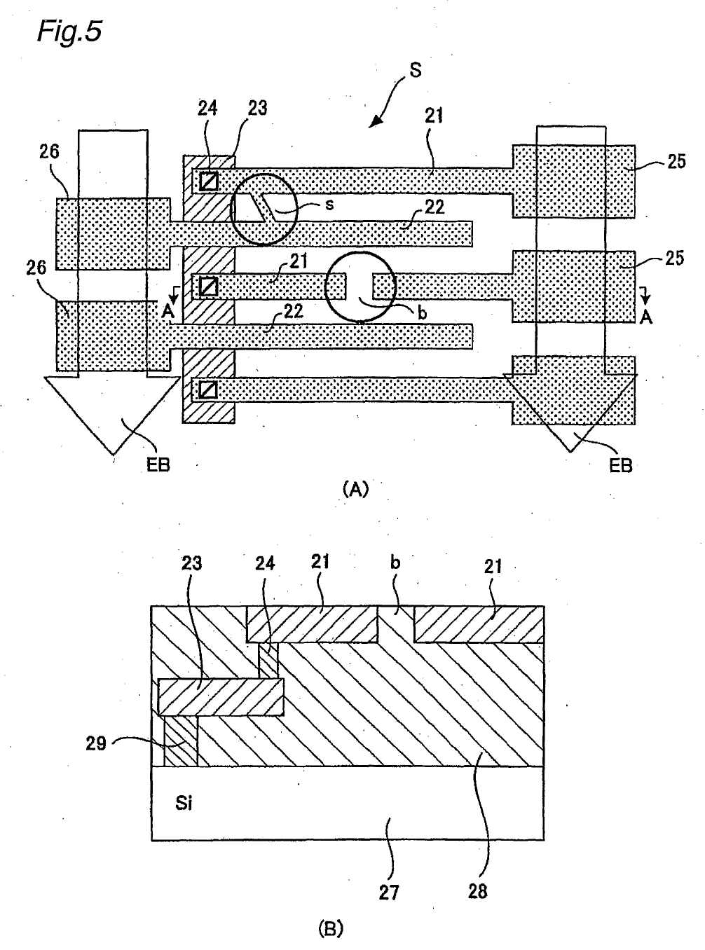

Next, a second embodiment of a semiconductor according to the present invention will be described with reference to FIGS. 5(A) and 5(B). A semiconductor device S according to the second embodiment has a semiconductor structure which comprises basic structures, each including the following components, which are two-dimensionally arranged on a periodic basis. FIG. 4 illustrates two basic structures.

(1) A first row wire formed in a first layer and comprising a single continuous wire 21;

(2) a second row wire formed in the first layer in parallel with the first row wire and comprising a single continuous wire 22;

(3) a ground electrode 23 formed in a second layer in a column direction so as to overlap left ends of the first row wire and second row wire;

(4) a via 24 connected to the ground electrode 23 at a left end of the first row wire;

(5) a conductor 25 connected to a right end of the first row wire; and

(6) a conductor 26 connected to a left end of the second row wire.

FIG. 5(B) generally illustrates a cross section along a line A-A in FIG. 5(A), where an insulating layer (SiO₂ layer) 28 is formed on an Si substrate 27, and the row wire 21, ground electrode 23, and via 24 are formed in the insulating layer 28. Reference numeral 29 designates a contact for connecting the ground electrode 23 with the Si substrate 27.

Since the second embodiment has the structure as described above, a broken point b, if occurring on the row wire 21 which should be essentially at the ground potential, will cause the right side from the broken point b, i.e., wires connected to the conductor 23 to transition to an open potential (floating potential). Therefore, when the conductors 26 are scanned using an electron beam EB, the conductors at the ground potential differ in the secondary electron emission amount from the conductors at the open potential. By taking advantage of this phenomenon, it is possible to detect the presence or absence of a line break on a row wire which should be essentially at the ground potential. Likewise, in this embodiment, since the conductors are formed on every other row wires at first and second ends, respectively, these conductors are arranged at a wiring pitch reduced to one-half of the row wires. Accordingly, since the width in the column direction is two times wider, they can be laid out approximately three times wider at maximum. Advantageously, the amount of emitted secondary electrons is increased approximately three times, as compared with before.

Further, when a short occurs between adjacent row wires, the row wires, which should be essentially at the open potential, transitions to the ground potential. It is possible to identify where the short has occurred by taking advantage of this phenomenon. For example, when a short has occurred at a position S shown in FIG. 5(A), the wire 22, which should essentially be at the open potential, transitions to the ground potential. Therefore, by scanning the conductors 26 using an electron beam EB, it is found that the amount of secondary electrons emitted from the conductor 26 formed on the wire 22 differs from the amounts of secondary electron beams emitted from conductors formed on other row wires at the open potential, thus making it possible to identify the row wire which suffers from the short.

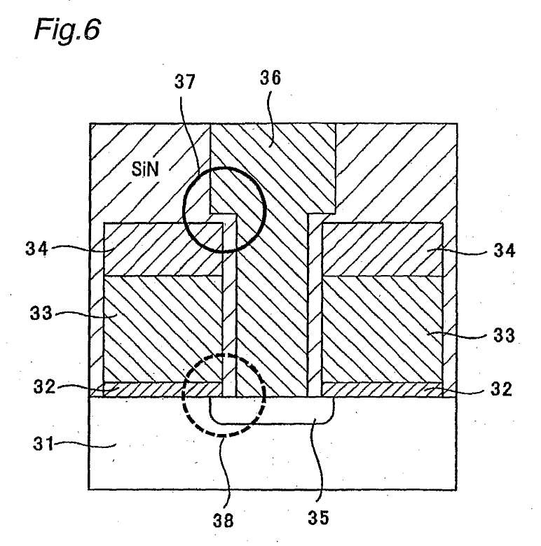

Next, a description will be given of examples in which the present invention is applied to a DRAM and a NAND type flash memory. Referring first to FIG. 6, conduction failures which can occur in these memories will be described. FIG. 6 is a cross-sectional view illustrating an exemplary structure near a bit contact within a memory array of a DRAM, which is similar to the structure near a source contact within a memory array of a NAND type flash memory. In FIG. 6, two gate insulating films 32 are formed on a substrate 31, and a poly Si layer 33 and a WSix layer 34, which make up gate electrodes, are laminated on the respective gate insulating films 32 to form a pair of gate electrodes. Further, between these gate electrodes, a bit contact 36 is formed for powering a diffusion layer 35 on the substrate 31. Though not shown, a bit line is connected to the top surface (surface opposite to the substrate 31) through a contact.

In any memory array, the poly Si layer 33 and WSiX layer 34 laminated thereon, which make up the gate electrode, are arranged to occupy a minimally required space in order to minimize the memory area, and the bit contact 36 made of poly Si or the like for powering the diffusion layer 35 between the gate electrodes is formed by a so-called self-alignment process. However, in the self-alignment process, a short tends to occur at a location 37 at which the WSix layer 34, which is the overlying layer of the gate electrode, is in close proximity to the bottom surface of the bit contact 36. Also, a short is likely to occur at a location 38 on the bottom of the bit contact 36 between the diffusion layer 35 and poly Si layer 33. If a short occurs at either of these locations 37, 38, the WSix layer 35 of the gate electrode transitions to the ground potential.

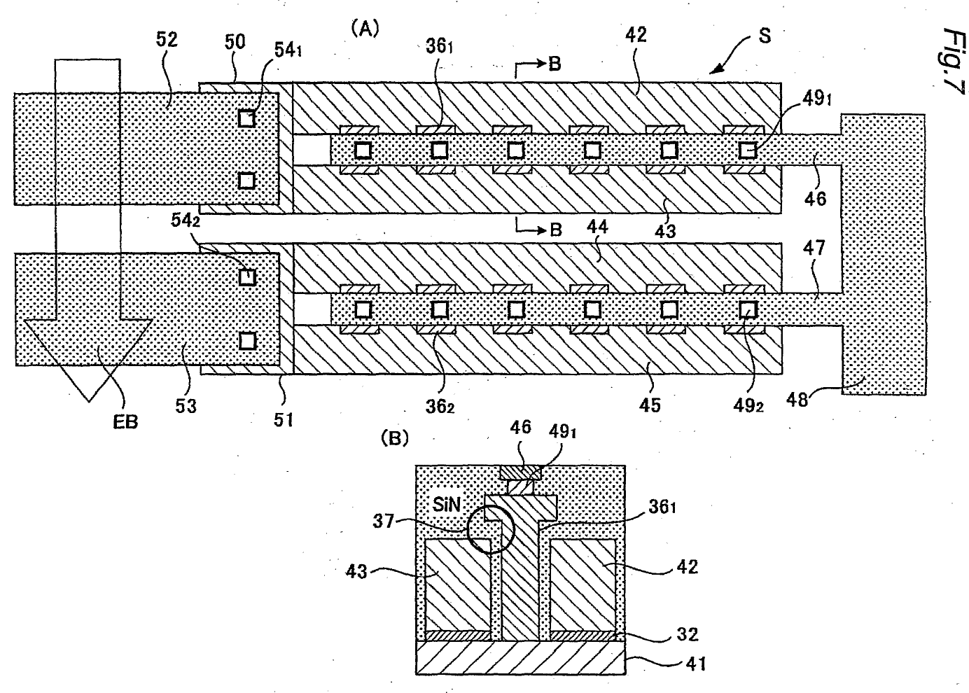

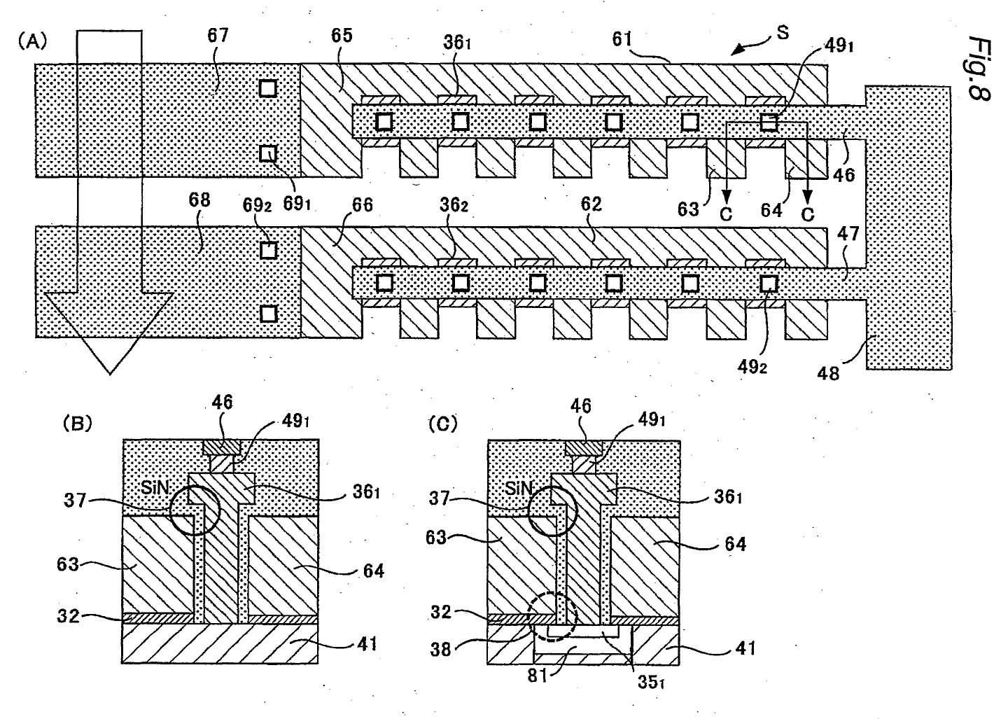

FIGS. 7(A) and 7(B) are diagrams generally illustrating a third embodiment of a semiconductor device according to the present invention for effectively detecting a location at which a short has occurred, as described above. FIG. 7(A) is a diagram illustrating a mutual positional relationship among components which make up a basic structure of a semiconductor device S, and FIG. 7(B) illustrates a cross-sectional view taken along a line B-B in FIG. 7(A). The semiconductor device S according to this embodiment employs the illustrated structure as a basic structure, and has a semiconductor structure which comprises a large number of the basic structures which are two-dimensionally arranged on a periodic basis.

As illustrated, the basic structure of the semiconductor device comprises the following components:

(1) a first pair of gate electrodes 42, 43 elongated in the row direction, and formed on a thick SiO₂ substrate (STI (Shallow Trench Isolation)) 41 through a gate insulating film 32;

(2) a second pair of gate electrodes 44, 45 elongated in the row direction, and formed on the substrate 41 through the gate insulating film 32 in parallel with the first pair of gate electrodes;

(3) a series of first bit contacts 36₁ formed at appropriate intervals between the first pair of gate electrodes 42, 43;

(4) a series of second bit contacts 36₂ formed at appropriate intervals between the second pair of gate electrodes 44, 45;

(5) a bit line composed of a first row wire 46 formed along a center line between the first pair of gate electrodes 42, 43, a second row wire 47 formed along a center line between the second pair of gate electrodes 44, 45, and a conductor 48 for connecting right ends of these row wires;

(6) a series of contacts 49₁ each for connecting the first bit contact 36₁ with the first row wire 46;

(7) a series of contacts 49₂ each for connecting the second bit contact 36₂ with the second row wire 47;

(8) a conductor 50 for connecting left-side ends of the first pair of gate electrodes 42, 43 to each other;

(9) a conductor 51 for connecting left ends of the second pair of gate electrodes 44, 45 to each other;

(10) a conductor 52 formed to overlap the conductor 50, and having substantially the same width as the first pair of gate electrodes in the column direction;

(11) a conductor 53 formed to overlap the conductor 51, and having substantially the same width as the second pair of gate electrodes in the column direction;

(12) a contact 54₁ for connecting between the conductor 52 and conductor 50; and

(13) a contact 54₂ for connecting between the conductor 53 and conductor 51.

In FIG. 7, assume that in a normal condition, the bit lines are at the ground potential, and all the gate electrodes are at the open potential. Supposing now that a short has occurred at a location 37 at which the top surface of one gate electrode 43 is in close proximity to the first bit contact 36₁, as illustrated in FIG. 7(B), the gate electrode 43, which should essentially be at the open potential, transitions to the ground potential, thus causing the conductor 52 connected to the gate electrode 43 to transition to the ground potential as well. Therefore, as the conductors 52, 53 are scanned using an electron beam EB, the conductor 52 at the ground potential presents a different voltage contrast from the conductor 53 at the open potential, so that by taking advantage of this voltage contrast signal, it can be determined on which row wire a short has occurred. Accordingly, a defective gate electrode can be identified only by creating a cross section of the gate electrode in a row wire which suffers from a conduction failure, thus making it possible to significantly reduce an analysis time and improve an analysis efficient as compared with before.

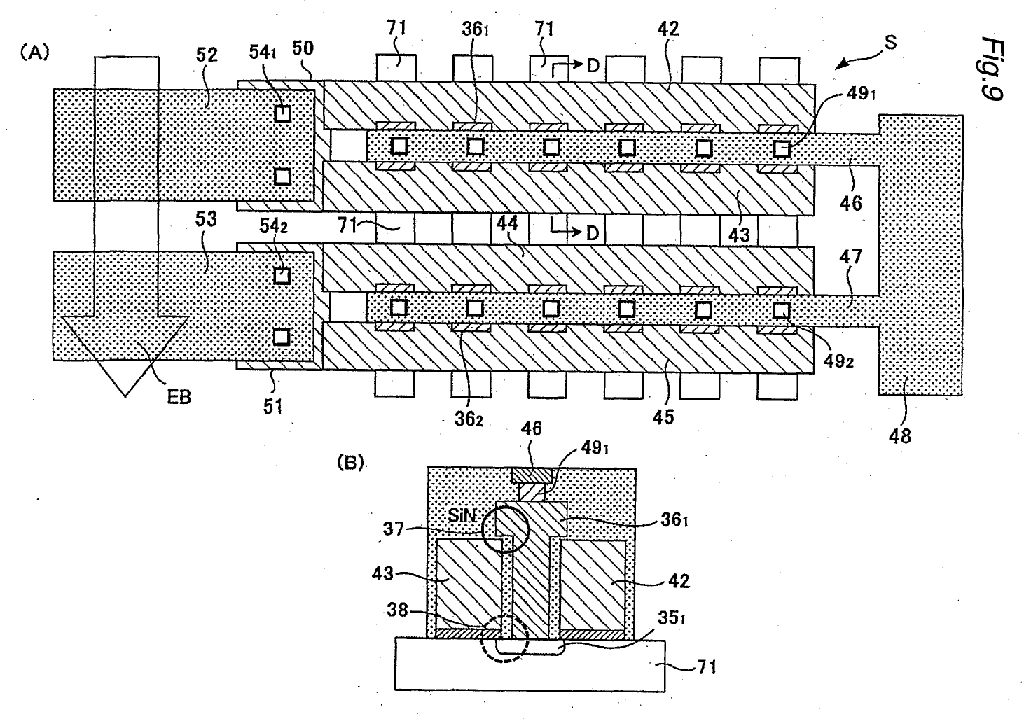

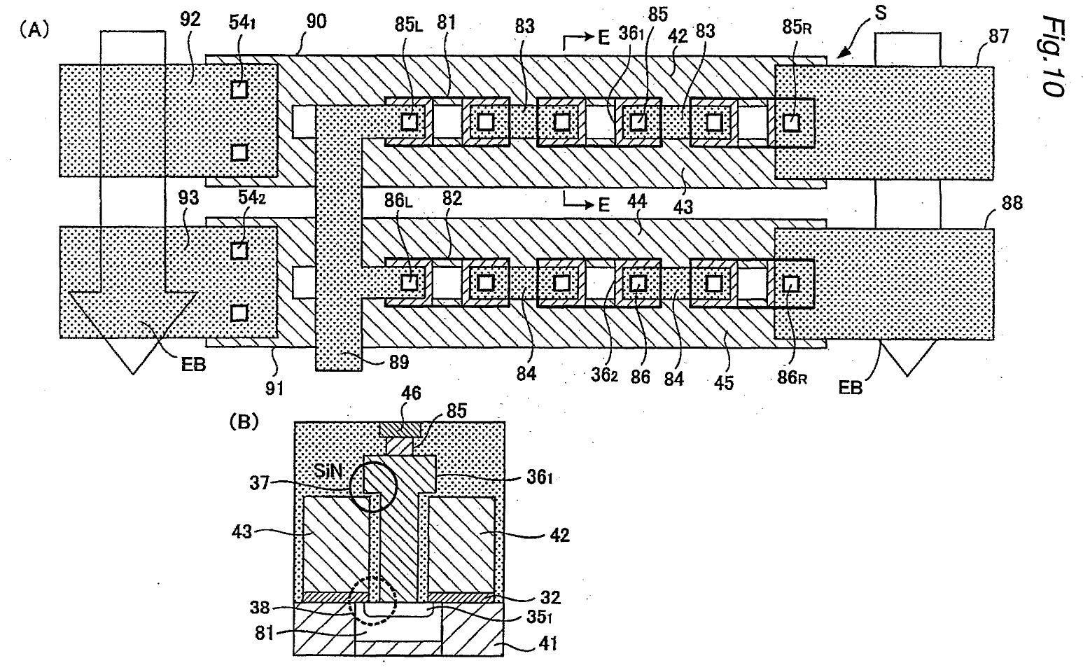

FIGS. 8(A) and 8(B) are diagrams generally illustrating a fourth embodiment of a semiconductor device according to the present invention, where FIG. 8(A) is a diagram illustrating a mutual positional relationship among components which make up a basic structure of a semiconductor device S, and FIG. 8(B) is a cross-sectional view taken along a line C-C in FIG. 8(A). This embodiment is adapted to have the ability to support new objects by replacing the pair of gate electrodes in the third embodiment described in FIG. 7 with gate electrodes in an interdigital shape extending in the column direction.

Likewise, in FIG. 8, the semiconductor device S employs the illustrated structure as a basic structure, and has a structure which comprises a large number of the basic structures which are two-dimensionally arranged on a periodic basis. In the fourth embodiment, the basic structure of the semiconductor device S comprises the following components:

(1) a first gate electrode 61 elongated in the row direction, and formed in an interdigital shape on a thick SiO₂ substrate (or STI (Shallow Trench Isolation)) 41 through a gate insulating film 32;

(2) a second gate electrode 62 elongated in the row direction, and formed in an interdigital shape on the substrate 41 through the gate insulating film 32 in parallel with the first gate electrode 61;

(3) a series of first bit contacts 36₁ each formed between adjacent digits 63, 64 in the first gate electrode 61;

(4) a series of second bit contacts 36₂ each formed between adjacent digits in the second gate electrode 62;

(5) a bit line composed of a first row wire 46 formed along a center line of the first gate electrode 61, a second row wire 47 formed along a center line of the second gate electrode 62, and a conductor 48 for connecting right ends of these row electrodes;

(6) first contacts 49₁ each for connecting the first bit contact 36₁ with the row wire 46;

(7) second contacts 49₂ each for connecting the second bit contact 36₂ with the row wire 47;

(8) a conductor 65 connected to a left end of the first gate electrode 61;

(9) a conductor 66 connected to a left end of the second gate electrode 62;

(10) a conductor 67 formed in a first layer to overlap the conductor 65, and having substantially the same width as the first gate electrode 61 in the column direction;

(11) a conductor 68 formed in the first layer to overlap the conductor 66, and having substantially the same width as the second gate electrode 62;

(12) a contact 69₁ for connecting between the conductor 65 and conductor 67; and

(13) a contact 69₂ for connecting between the conductor 66 and conductor 68.

In the fourth embodiment of FIG. 8, a short between the bit contact 36₁, 36₂ and gate electrodes 61, 62 is more probable to occur in the lengthwise direction of the gate electrode. Specifically, it is a location between a digit and a bit contact at which a short occurs in each bit contact with high probability, for example, a location 37 surrounded by a bold circle in FIG. 8(B). Supposing now that in a normal condition, the bit line is at the ground potential, and the gate electrode are at the open potential, as is the case with the third embodiment, if a short occurs between any bit contact and a digit of the gate electrode, the gate electrode transitions to the ground potential, thus causing the conductor 67 or 68 connected to this gate electrode to transition to the ground potential. Accordingly, as the conductors 67, 68 are scanned using an electron beam EB, a different voltage contrast signal is generated depending on whether these conductors are at the ground potential or open potential. In this way, it is possible to identify in which gate electrode a short has occurred.

Conventionally, when it is revealed from a voltage contrast test that a short has occurred anywhere on a certain gate electrode, an examination made to find on which bit contact a short has occurred generally involves dividing all bit contacts in the vertical and row directions, or locally creating a cross section in the vertical and row directions using a forecast ion beam technique, and observing the cross section using a secondary electron microscope (SEM). However, this strategy requires an immense time and labor because a defectively conductive location cannot be found unless cross sections are created for all bit contacts.

In the fourth embodiment illustrated in FIG. 8, the digits 63, 64 of the interdigital gate electrode are oriented in the row direction, and the bit contacts are arranged in a line such that they are positioned between adjacent digits, so that when a defectively conductive word conductor is found by scanning the conductors using an electron beam as described above, only one cross sectional may be created for that gate electrode, thus making it possible to significantly reduce an analysis time, and improving an analysis efficiency as before.

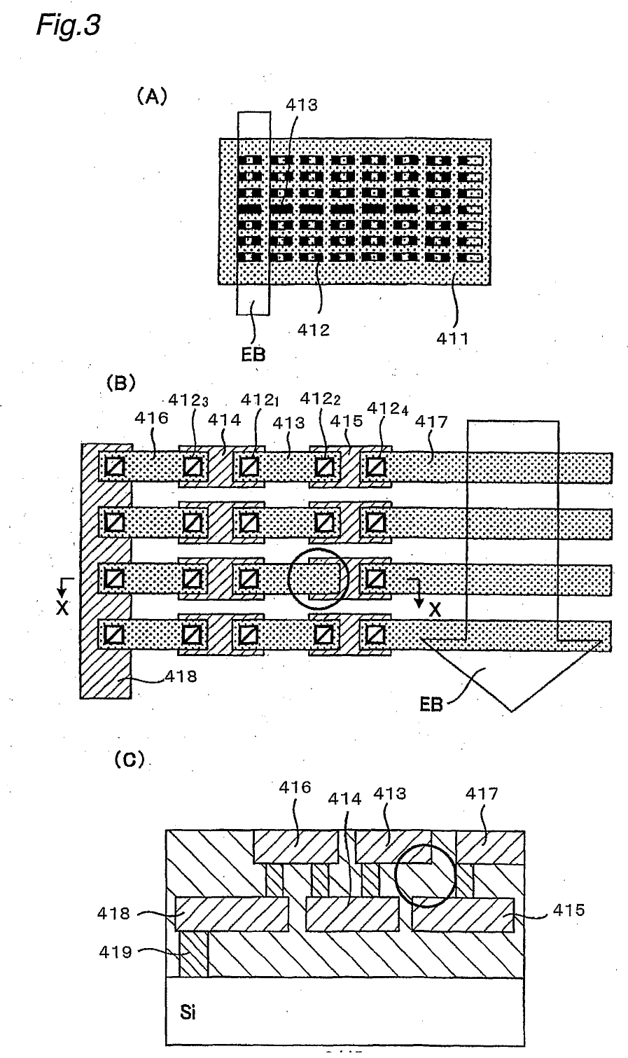

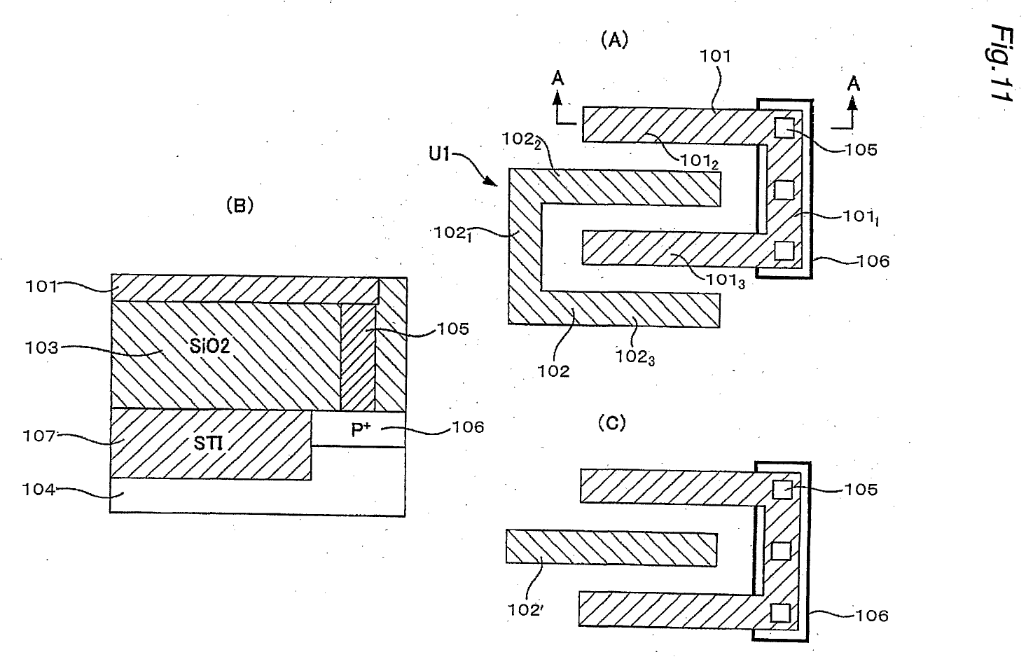

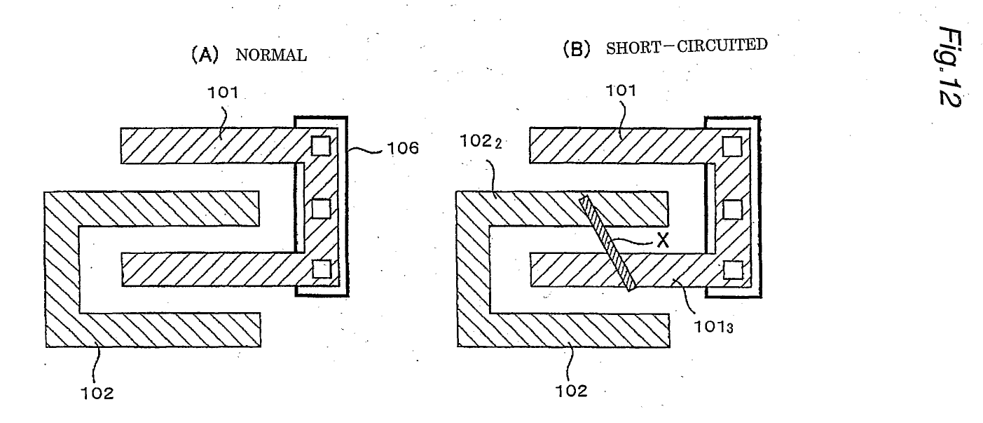

FIGS. 9(A) and 9(B) are diagrams generally illustrating a fifth embodiment of a semiconductor device according to the present invention, where FIG. 9(A) is a diagram illustrating a mutual positional relationship among components which make up a basic structure of a semiconductor S, and FIG. 9(B) is a cross-sectional view taken along a line D-D. In FIG. 9(A), as has been previously described in connection with FIG. 3, a self-aligned contact tends to suffer from a short at two upper and lower locations 37, 38 of a gate electrode. A short at the upper location can be detected by using the embodiments shown in FIGS. 7 and 8. Accordingly, the fifth embodiment provides an active area in the structure of FIG. 7 in order to detect such a short at the lower location as well.

As illustrated in FIG. 9(A), the semiconductor device S employs the illustrated structure as a basic structure, and has a structure which comprises a large number of the basic structures which are two-dimensionally arranged on a periodic basis. In the fifth embodiment, the basic structure of the semiconductor device S comprises the following components:

(1) a first pair of gate electrodes 42, 43 elongated in the row direction;

(2) a second pair of gate electrodes 44, 45 elongated in the row direction, and formed in parallel with the first pair of gate electrodes 44, 45;

(3) a series of first bit contacts 36₁ formed at appropriate intervals between the first pair of gate electrodes 42, 43;

(4) a series of second bit contacts 36₂ formed at appropriate intervals between the second pair of gate electrodes 44, 45;

(5) a bit line composed of a first row wire 46 formed along a center line of the first pair of gate electrodes 42, 43, a second row wire 47 formed along a center line of the second pair of gate electrodes 44, 45, and a conductor 48 for connecting right ends of these row wires;

(6) a series of contacts 49₁ each for connecting the first bit contact 36₁ with the first row wire 46;

(7) a series of contacts 49₂ each for connecting the second bit contact 36₂ with the second row wire 47;

(8) a conductor 50 for connecting left ends of the first pair of the gate electrodes 42, 43;

(9) a conductor 51 for connecting left ends of the second pair of the gate electrodes 44, 45;

(10) a conductor 52 formed to overlap the conductor 50, and having substantially the same width as the first pair of gate electrodes 42, 43 in the column direction;

(11) a conductor 53 formed to overlap the conductor 51, and having substantially the same width as the second pair of the gate electrodes 44, 45 in the column direction;

(12) a contact 54₁ for connecting between the conductor 52 and conductor 50;

(13) a contact 54₂ for connecting between the conductor 53 and conductor 51;

(14) first diffusion layers 35₁ each connected to a lower end of the first bit contact 36₁;

(15) second diffusion layers 35₂ (not shown) each connected to a lower end of the second bit contact 36₂; and

(16) a series of active area 71 having the first diffusion layers 35₁ and second diffusion layers 35₂ on the surface, and formed on an Si substrate in a direction orthogonal to the first pair of the gate electrodes 41, 42 and the second pair of the gate electrodes 43, 44.

In FIG. 9, assume that in a normal condition, bit lines are at the ground potential, and the first pair of the gate electrodes 42, 43 and the second pair of the gate electrodes 44, 45 are at the open potential. Supposing now that a short is occurring at a location 37 indicated by a bold circle between the top surface of one gate electrode 42 and the bit contact 36₁, the gate electrode 43, which should essentially be at the open potential, transitions to the ground potential, so that the conductor 52 connected to the gate electrode 43 also transitions to the ground potential. Therefore, as the conductors 52, 53 are scanned using an electron beam EB, the conductor 52 at the ground potential presents a different voltage contrast from the conductor 53 at the open potential, so that by taking advantage of this voltage contrast signal, it is possible to identify the row wire on which the short has occurred. Accordingly, a defective gate electrode can be identified only by creating a cross section of the gate electrode in a row wire which suffers from a conduction failure, thus making it possible to significantly reduce an analysis time and improve an analysis efficient as compared with before.

Likewise, if a short occurs at the location 38 on the bottom of the bit contact 36, as indicated by a dotted circle in FIG. 9(B), the gate electrode 43 transitions to the ground potential, thus causing the conductor 52 connected to the gate electrode 43 to transition to the ground potential as well. Accordingly, as all conductors 52, 53 are scanned using an electron beam EB, the conductor 52 at the ground potential presents a different voltage contrast from that of the conductor 53 at the open potential.

Therefore, for determining whether a short has occurred at the upper location 37 or lower location 38 in the semiconductor device illustrated in FIG. 9, a comparison may be made between yield rates of TEG's in the semiconductor device illustrated in FIG. 7 and the semiconductor device illustrated in FIG. 9. This is because a short can occur only at the upper location 37 in the semiconductor device illustrated in FIG. 7, whereas a short can occur at the two upper and lower locations 37, 38 in the semiconductor device illustrated in FIG. 9. When it is found from such a comparison between the yield rates that the yield rate of the semiconductor device in FIG. 9 is lower than the yield rate of the semiconductor device in FIG. 7, it can be determined that a short occurs at the lower location 38 as well in the semiconductor device in FIG. 9. Also, in the fifth embodiment, since either of the short at the upper location and the short at the lower location can be detected in a bit contact, it is also possible to classify as to which of the short at the upper location and the short at the lower location in the bit contact presents a short occurrence frequency within the same wafer.

In FIG. 9, the active area 71 is formed to protrude from both sides (in an upper limit direction in the figure) of the first pair of the gate electrodes 42, 43 and the second pair of the gate electrodes 44, 45, but the active area 71 need not be necessarily protruded. The active area 71 is only required to at least overlap the respective row wires. However, the structure illustrated in FIG. 9 is more advantageous in that the design is facilitated because extra efforts are not required such as a calculation of an alignment allowance.

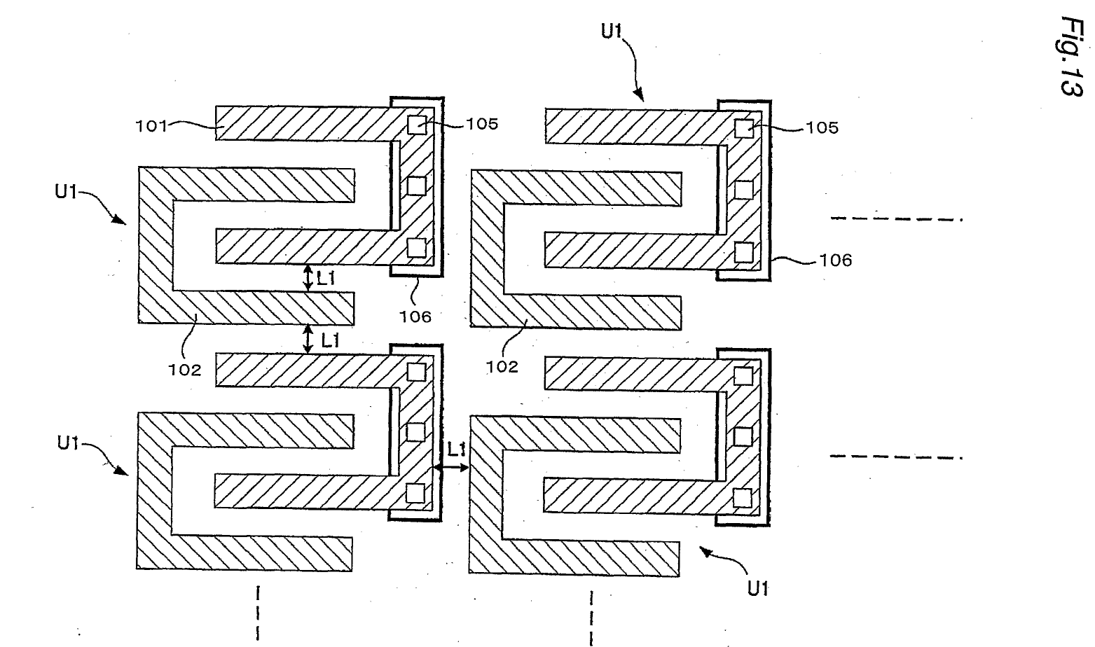

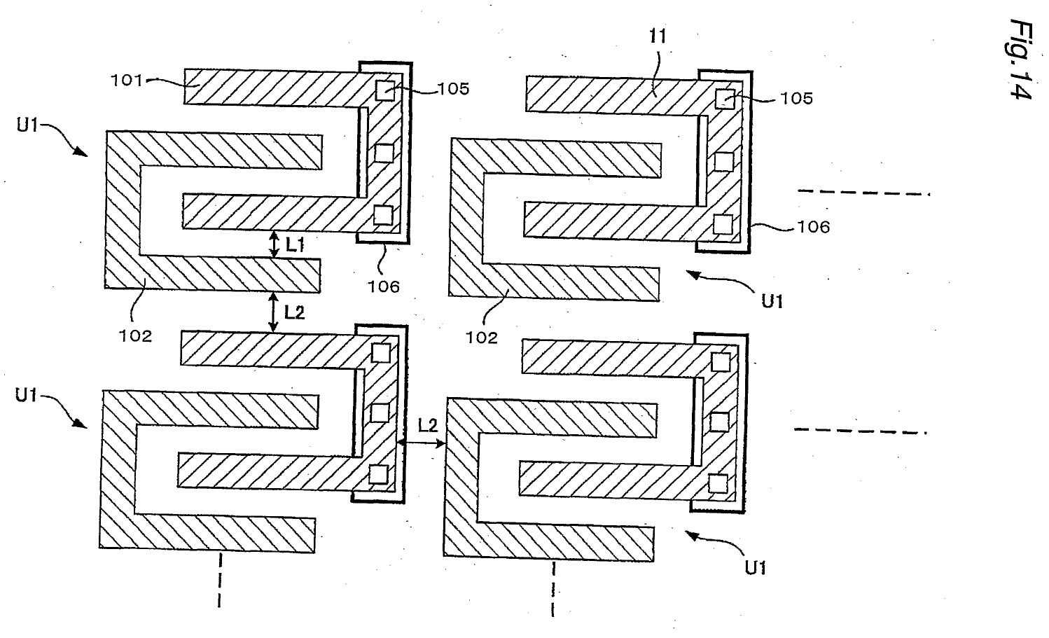

Next, FIGS. 10(A) and 10(B) are diagrams generally illustrating a sixth embodiment of a semiconductor device according to the present invention, where FIG. 10(A) illustrates a mutual positional relationship among components which make up a basic structure of a semiconductor device S, and FIG. 10(B) is a cross-sectional view taken along a line E-E in FIG. 10(A). In this embodiment, areas adjacent to bit contacts and gate electrodes are all arranged in a line.

In FIG. 10(A), the semiconductor device S employs the illustrated structure as a basic structure, and comprises a large number of the basic structures which are two-dimensionally arranged on a periodic basis. The semiconductor device S in the sixth embodiment comprises the following components:

(1) a first pair of gate electrodes 42, 43 elongated in the row direction, and formed on a thick SiO₂ substrate (or STI (Shallow Trench Isolation)) 41 through a gate insulating film 32;

(2) a second pair of gate electrodes 44, 45 elongated in the row direction, and formed on the thick SiO₂ substrate (or STI (Shallow Trench Isolation)) 41 through the gate insulating film 32 in parallel with the first pair of gate electrodes;

(3) a series of first bit contacts 36₁ formed at appropriate intervals between the first pair of the gate electrodes 42, 43;

(4) a series of second bit contact 36₂ formed at appropriate intervals between the second pair of the gate electrodes 44, 45;

(5) a first active area 81 intermittently formed on the SiO₂ substrate (or STI) 41 so as to have a diffusion layer 35₁ on the surface, where two adjacent bit contacts of the series of the first bit contacts 36₁ are connected to the diffusion layer 35₁;

(6) a second active area 82 intermittently formed on the SiO₂ substrate (or STI) 41 so as to have a diffusion layer 35₂ (not shown) on the surface, where two adjacent bit contacts of the series of the second bit contacts 36₂ are connected to the diffusion layer 35₂;

(7) a series of first wires 83 formed to connect two adjacent bit contacts of the series of the first bit contacts 36₁;

(8) a series of second wires 84 formed to connect two adjacent bit contacts of the series of the second bit contacts 36₂;

(9) first contacts each for connecting each of the series of the first bit contacts 36₁ to a first wire 83 corresponding thereto;

(10) second contacts each for connecting each of the series of the second bit contacts 36₂ to a second wire 84 corresponding thereto;

(11) a first conductor 87 connected to a contact 85_{R} located at a right end of the first contacts 85, and having substantially the same width as the first pair of the gate electrodes 42, 43 in the column direction;

(12) a second conductor 88 connected to a contact 86_{R} located at a right end of the second contacts 86, and having substantially the same width as the second pair of the gate electrodes 44, 45 in the column direction;

(13) a third conductor 89 for connecting left ends of contacts 85_{L}, 86_{L} located at left ends of the first contacts 85 and second contacts 86;

(14) a fourth conductor 90 for connecting left ends of the first pair of the gate electrodes 42, 43;

(15) a fifth conductor 91 for connecting left ends of the second pair of the gate electrodes 44, 45;

(16) a sixth conductor 92 formed to overlap the fourth conductor 90, and having substantially the same width as the first pair of gate electrodes in the column direction;

(17) a seventh conductor 93 formed to overlap the fifth conductor 91, and having substantially the same width as the second pair of gate electrodes in the column direction;

(18) a contact 54₁ for connecting the conductor 90 to the conductor 92; and

(19) a contact 55₂ for connecting the conductor 91 to the conductor 93.

In the structure illustrated in FIG. 10, assume that in a normal condition, the conductor 89 is at the ground potential, so that the wires 83, 84 and conductors 87, 88 are also at the ground potential, whereas the first pair of the gate electrodes 42, 43 and the second pair of the gate electrodes 44, 45 are at the open potential. Supposing now that a short occurs at a location 37 indicated by a bold circle in FIG. 10(B) between the upper surface of one gate electrode 42 and any bit contact 36₁, as illustrated in FIG. 10(B), the gate electrode 43, which should essentially be at the open potential, transitions to the ground potential, thus causing the conductor 92 connected to the gate electrode 43 to transition to the ground potential as well. Accordingly, as the conductor 92 and conductor 93 are scanned using an electron beam EB, the conductor 92 at the ground potential presents a different voltage contrast from that of the conductor 93 at the open potential. As has been previously described in connection with the other embodiments, it is possible to identify a gate electrode at which a short has occurred by taking advantage of the voltage contrast signal.

Also, if a conduction failure occurs at any location, for example, no conduction is made between the contact 85 and wire 83, the conductor 87 located on the right side of the location at which the conduction failure has occurred transitions to the open potential, so that when the conductors are scanned using an electron beam EB, the conductor 87 presents a different secondary electron emission rate from the conductor 88 at the ground potential. By taking advantage of this phenomenon, it is possible to identify which pair of gate electrodes suffers from a conduction failure.

Likewise, if a short has occurred at the location 38 on the bottom of the bit contact 36₁, as indicated by a dotted line circle in FIG. 10(B), the gate electrode 43 also transitions to the ground potential, thus causing the conductor 92 connected to the gate electrode 43 to transition to the ground potential as well. Accordingly, as all the conductors 92, 93 on the left side are scanned using an electron beam EB, the conductor 92 at the ground potential presents a different voltage potential from that of the conductor 93 at the open potential. Therefore, in a manner similar to that described in the fifth embodiment illustrated in FIG. 9, it can be determined whether or not a short has occurred at the lower location 38 by comparing yield rates in TEG's. Also, since either of a short at the upper location and a short at the lower location can be detected in a bit contact, it is also possible to classify as to which of the short at the upper location and the short at the lower location in the bit contact presents a short occurrence frequency within the same wafer.

Now, turning back to the fourth embodiment illustrated in FIGS. 8(A) and 8(B), the fourth embodiment can also be modified to include an active area in the row direction, as will be understood from the description on the sixth embodiment illustrated in FIG. 10. This exemplary modification will be described with reference to FIG. 8(C). FIG. 8(C) is a cross-sectional view taken along a line C-C when an active area, later described, is formed in FIG. 8(A). In FIG. 8(C), a first active area 81 having a width equivalent to that of the first row wire 46 is formed in the SiO₂ substrate (or STI) 41 so as to have, on its surface, diffusion layers 35₁ connected to lower ends of the series of the first bit contacts 36₁, respectively, and so as to partially overlap digits 63, 64 which are adjacent in the lengthwise direction of the first row wire 46. As a result, the active area 81 is intermittently formed along the first row wire 46. Alternatively, the active area 81 may be formed in a straight line along the first row wire 46. Similar to this, the second active area 82 is formed in the same shape as the first active area 81 intermittently or in a straight line in the lengthwise direction of the second wire line 47. In this way, as has been previously described for the embodiment illustrated in FIGS. 8(A) and 8(B), it is possible to identify a gate electrode in which a short has occurred at the upper location 37. In addition, when a short has occurred at the lower location 38, the gate electrodes 61, 62 on the side where the short has occurred transition to the ground potential, thus causing the conductors 67, 68 connected to the gate electrodes, which has transitioned to the ground potential, to transition to the ground potential as well. Accordingly, as all the conductors 67, 68 on the left side are scanned using an electron beam EB, the conductor at the ground potential presents a different voltage contrast from the conductor at the open potential. Therefore, in a manner similar to that described in the fifth embodiment illustrated in FIG. 9, it is possible to determine whether or not a short has occurred at the lower location 38 as well by comparing the yield rates in TEG's with each other. Also, since either of a short at the upper location and a short at the lower location can be detected in a bit contact, it is also possible to classify as to which of the short at the upper location and the short at the lower location in the bit contact presents a short occurrence frequency within the same wafer.

As will be understood from the foregoing description, when the embodiment illustrated in FIG. 7 or FIG. 8 and the embodiment illustrated in FIG. 10 are implemented on the same wafer, it is possible to classify as to which of a short at the upper location and non-conduction occurs more frequently on the same wafer.

FIGS. 11(A), 11(B) and 11(C) are diagrams generally illustrating a basic wiring pattern and structure in the seventh embodiment of a semiconductor device according to the present invention, where FIGS. 11(A) and 11(C) are top plan views, and FIG. 11(B) is a cross-sectional view taken along a line A-A. As illustrated in FIG. 11(A), a basic wiring pattern U1 of the semiconductor device comprises a first wire 101 which is grounded and formed in an inverted C-shape; and a second wire 102 interdigitally arranged with the first wire 101, set at the floating potential and designed in a structure symmetric to the first wire 101. The C-shaped first wire 101 and second wire 102 are made, for example, of copper, and have bases 101₁, 102₁, and interdigital conductors 101₂, 101₃, 102₂, 102₃, respectively.

Specifically, as illustrated in FIG. 11(B), the first wire 101 and second wire 102 are formed on the top surface of an SiO₂ layer 103 by an appropriate method. The SiO₂ layer 103 is formed on an Si substrate 104, while the Si substrate 104 is formed with an active area 106 electrically connected to the base 101₁ of the first wire 101 through a contact 105, and with an STI (Shallow Trench Isolation) 107 around the active area 106. The second wire 102 is not electrically connected to other elements. In this way, the first wire is set at the ground potential, while the second wire 102 is set at the floating potential.

Now, when this basic wiring pattern U1 is scanned using an electron beam to display the amount of secondary electrons emitted from each wire, the grounded first wire 101, for example, is displayed light because it emits a lot of secondary electrons, whereas the second wire 102 at the floating potential is displayed dark because it emits a small amount of secondary electrons in a normal condition illustrated in FIG. 12(A), though depending on the energy of irradiated electrons. On the other hand, if a short occurs due to a foreign substance X between the interdigital conductor 102₂ at the floating potential and the interdigital conductor 101₃ at the ground potential, as illustrated in FIG. 12(B), the first wire 101 and second wire 102 transition to the ground potential. Thus, as the basic wiring pattern U1 is scanned using an electron beam in this state, the entire wires emit a lot of secondary electrons, and are therefore displayed light on the display device.

As described above, in the conventional structure illustrated in FIG. 1, the voltage contrast changes by one wire at a location at which a short has occurred, whereas in the first embodiment illustrated in FIG. 11, by creating the basic wiring pattern U1 in combination of a wire at the floating potential with a wire at a ground potential, when a short occurs anywhere in the basic wiring pattern, all wires in this basic wiring pattern transition to the same potential, resulting in the same voltage contrast in the entire area of the basic wiring pattern. Therefore, a change in the voltage contrast can be detected in this area at a relatively large detection resolution and at a higher testing speed.

While the second wire 102 is also in the inverted C-shape in FIG. 11(A), the second wire 102 may have only a single wire 102′ of the same length as the interdigital conductors 102₂, 102₃, as illustrated in FIG. 11(C), where similar effects can be provided.

Actually, in a semiconductor device, multiple basic wiring patterns U1 in the seventh embodiment are arranged vertically and horizontally in matrix. Specifically, FIGS. 13 and 14 illustrate the basic wiring patterns U1 shown in FIG. 11, each of which constitutes one unit, arranged in a matrix of m rows and n columns. Therefore, as a short occurs in any basic wiring pattern of the basic wiring patterns arranged in m rows and n columns, the amount of secondary electrons emitted from the basic wiring pattern, in which the short has occurred, increases or decreases as compared with the remaining units, so that this basic pattern is displayed lighter or darker than surrounding basic wiring patterns on a display device. In this way, it is possible to identify the basic wiring pattern in which the short has occurred.

Specifically, in FIG. 13, all the basic wiring patterns are arranged such that the first wire 101 and second wire 102 are positioned in such a manner that their respective interdigital conductors are spaced apart by a distance L1 from each other in each basic wiring pattern, and such that adjacent basic wiring patterns are also spaced apart by the distance L1 from one another. In this way, the probability that a short occurs between wires within each basic wiring pattern is the same as the probability that a short occurs between basic wiring patterns. Actually, however, when a short occurs between the basic wiring patterns, the position at which the short occurred slightly shifts from a position of the basic wiring pattern at which the occurrence of the short is detected, so that a subsequent analysis can take a longer time.

To solve this problem, in FIG. 14, a plurality of basic wiring patterns U1 are arranged in a matrix of m rows and n columns in a manner similar to FIG. 13, wherein the first wire 101 and second wire 102 are positioned so that their respective interdigital conductors are spaced apart from each other by the distance L1 in each basic wiring pattern, but adjacent basic wiring patterns are spaced apart from one another by a distance L2 larger than the distance L1. In this way, it is possible to reduce the probability that a short occurs between basic wiring patterns to alleviate the problem in the matrix illustrated in FIG. 13.

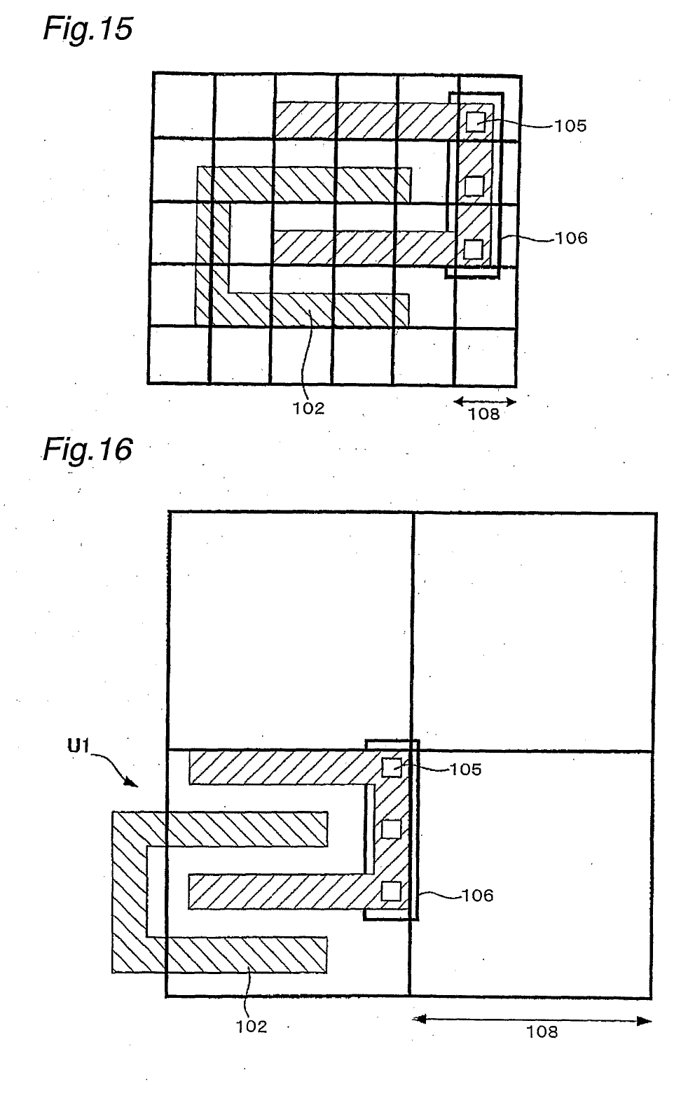

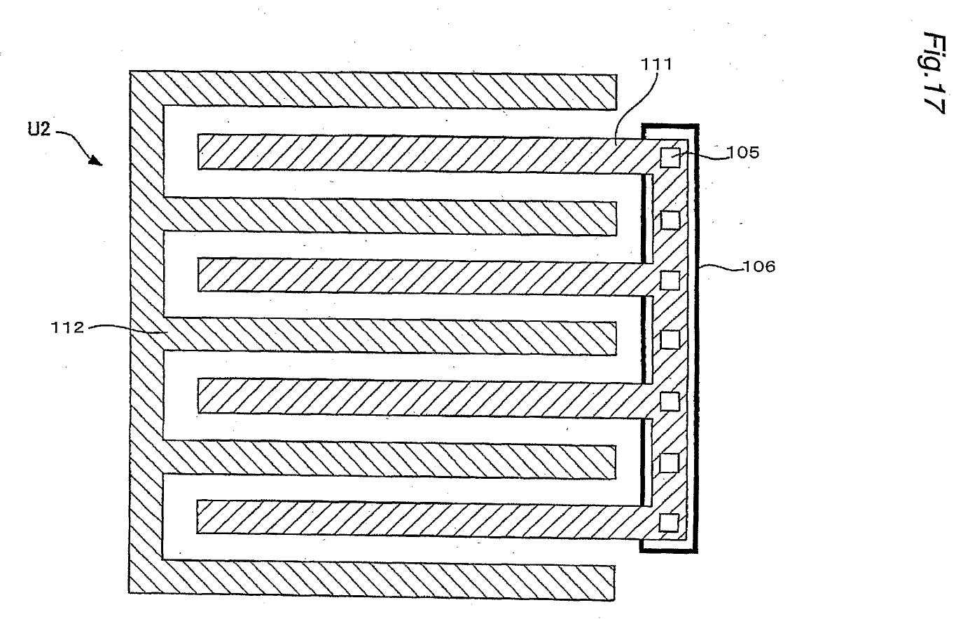

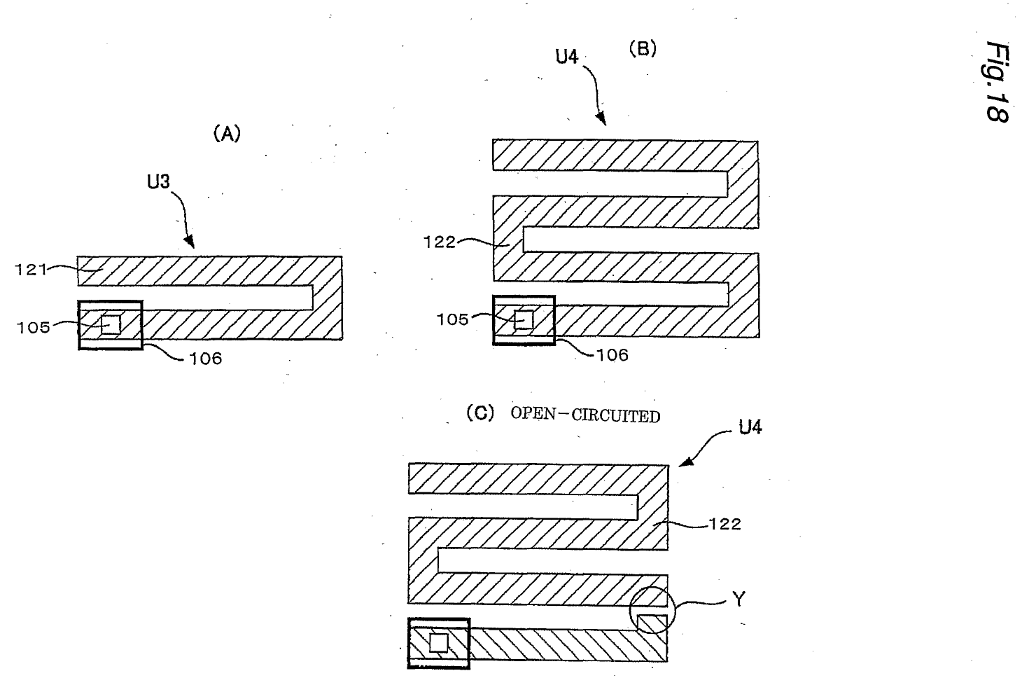

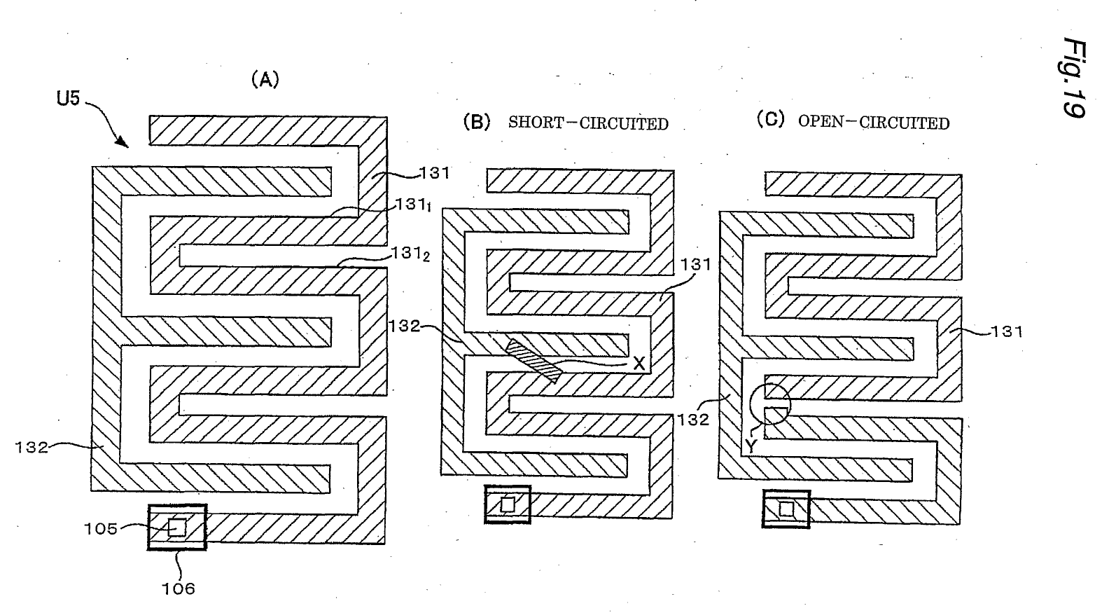

Referring now to FIGS. 15 and 16, a description will be given of a maximum value and a minimum value of a detection resolution (i.e., a pixel size) for detecting the basic wiring pattern in the seventh embodiment of the present invention. FIG. 15 shows a minimum value for the pixel size, where a pixel size 108 required to detect a single basic wiring pattern U1 is similar to the wiring pitch of the basic wiring patterns U1, i.e., the sum of the distance L1 in FIG. 14 and the wire width. On the other hand, FIG. 16 shows a maximum value for the pixel size, which is substantially the same value as the size of one basic wiring pattern along an electron beam scanning direction. Assuming, for example, that the pixel size is set to the maximum value, when the pattern matrix illustrated in FIG. 13 or 14 is scanned using an electron beam in the manner described above, a light/dark pattern varies on a display device in units of basic wiring pattern in which a wire short has occurred, resulting from a change in the amount of emitted secondary electrons, so that even if the pixel size is set to be substantially the same as the size of one basic wiring pattern, the voltage contrast can be detected between the basic wiring patterns. It goes without saying that as the pixel size is increased, an increased area can be tested at a time, thus reducing a testing time in reciprocal proportion to the area.

FIG. 17 is a diagram generally illustrating a basic wiring pattern in an eighth embodiment of a semiconductor device according to the present invention. The basic wiring pattern U2 in this embodiment can be said to be expanded from the basic wiring pattern U1 in the seventh embodiment. Specifically, the basic wiring pattern U2 comprises an interdigital first wire 111 and second wire 112 each having three or more interdigital conductors which are interdigitally arranged. The interdigital conductors of the respective wires are formed longer than the interdigital conductors in the first embodiment. Therefore, if a short occurs between any interdigital conductors, a larger voltage contrast signal can be advantageously generated than in the seventh embodiment.

FIGS. 18(A) and 18(B) are diagrams generally illustrating basic wiring patterns in a ninth embodiment of a semiconductor device according to the present invention, showing a structure for detecting an open-circuit failure. In FIG. 18(A), a basic wiring pattern U3 includes an inverted C-shaped wire 121 which has a pair of interdigital conductors, one of which has an end connected to an active area 106 of a substrate 101 through a contact 105, whereas in FIG. 18(B), a basic wiring pattern U4 includes a zig-zag wire 122, one end of which is connected to an active area 106 of a substrate 101 through a contact 105.

Therefore, assuming that an open-circuit failure has occurred at any location Y on the wire 122 as illustrated in FIG. 18(C), when the basic wire pattern U4 is scanned using an electron beam, the basic wire pattern U4 is divided into sections, which differ in the amount of emitted secondary electrons, at a boundary which is the opened location Y, thus making it possible to generate a large voltage contrast signal. Likewise, for the basic wiring pattern U3 illustrated in FIG. 18(A), if an open occurs halfway on the wire, a lighter portion and a darker portion are displayed on a display device in a similar manner, so that a large voltage contrast signal can be generated.

The foregoing description has been given of the wiring structures of the basic wiring patterns for detecting the occurrence of short and open. Now, these wiring structures can be combined to derive wiring structures for detecting a short and an open. FIG. 19 is a diagram generally illustrating a basic wiring pattern in a tenth embodiment of a semiconductor device according to the present invention. In this figure, the basic wiring pattern U5, which has a relatively large area, comprises a first zig-zag wire 131 and a second E-shaped wire 132, which are interdigitally arranged, where one end of the first wire 131 is connected to an active area 106 through a contact 105. In this way, the first wire 131 is set to the ground potential, while the second wire 132 is at the floating potential.

In the basic wiring pattern U5, the first wire 131 at the ground potential is used for detecting an open-circuit failure, and the second wire 132 at the floating potential is used for detecting a short-circuit failure. Specifically, when a short occurs due to a foreign substance X between the first wire 131 and second wire 132 at any location of the basic wiring pattern U5, as illustrated in FIG. 19(B), both wires 131, 132 transition to the ground potential, so that, as a result of a scan using an electron beam, the entire image of the basic wiring pattern U5 is displayed to be light or dark, thereby making it possible to detect the occurrence of the short. On the other hand, when an open occurs at a location Y of the first wire 131, the basic wiring pattern U5 is divided into a section which is at the ground potential, and a section which is at the floating potential, so that, as a result of a scan using an electron beam, the image of the basic wiring pattern U5 is divided into a light and a dark area corresponding to the section at the ground potential and the section at the floating potential, thereby making it possible to detect the occurrence of the open. In this tenth embodiment, the image, which is divided into a dark and a light area upon occurrence of a failure, largely differs from the image of the normal basic wiring pattern U5, so that a short and an open can be readily detected.

In the structure of FIG. 19(A), a pair of interdigital conductors of the first wire 131 are inserted between a pair of interdigital conductors of the second wire 132, but alternatively, a plurality of interdigital conductors may be inserted between a pair of interdigital conductors of the second wire 132.

By the way, the embodiment of FIG. 19 is structured such that the interdigital conductors in the first wire 131, for example, the interdigital conductors 131₁, 131₂ oppose in all the wires of the basic wiring pattern U5. As such, even if a short occurs between the opposing interdigital conductors, this cannot be detected, thus presenting a low space efficiency from a viewpoint of detecting the occurrence of a short.

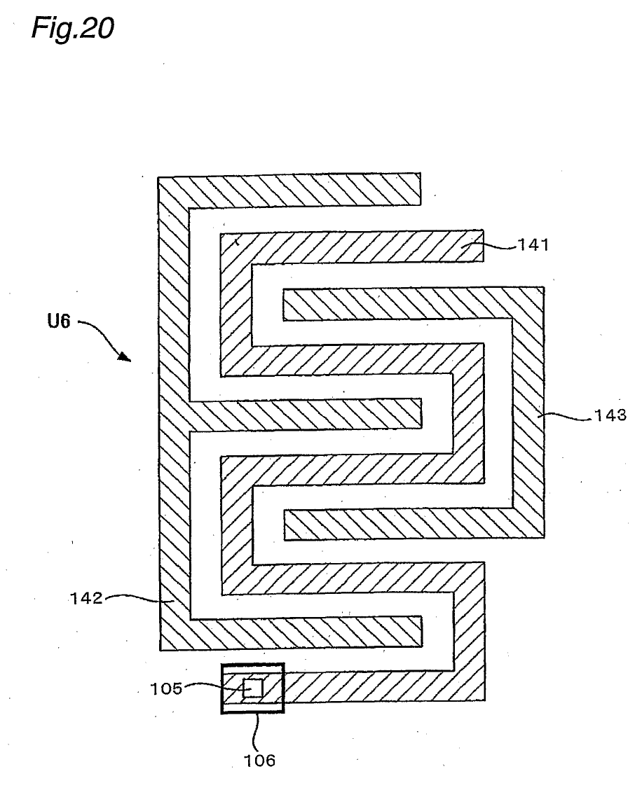

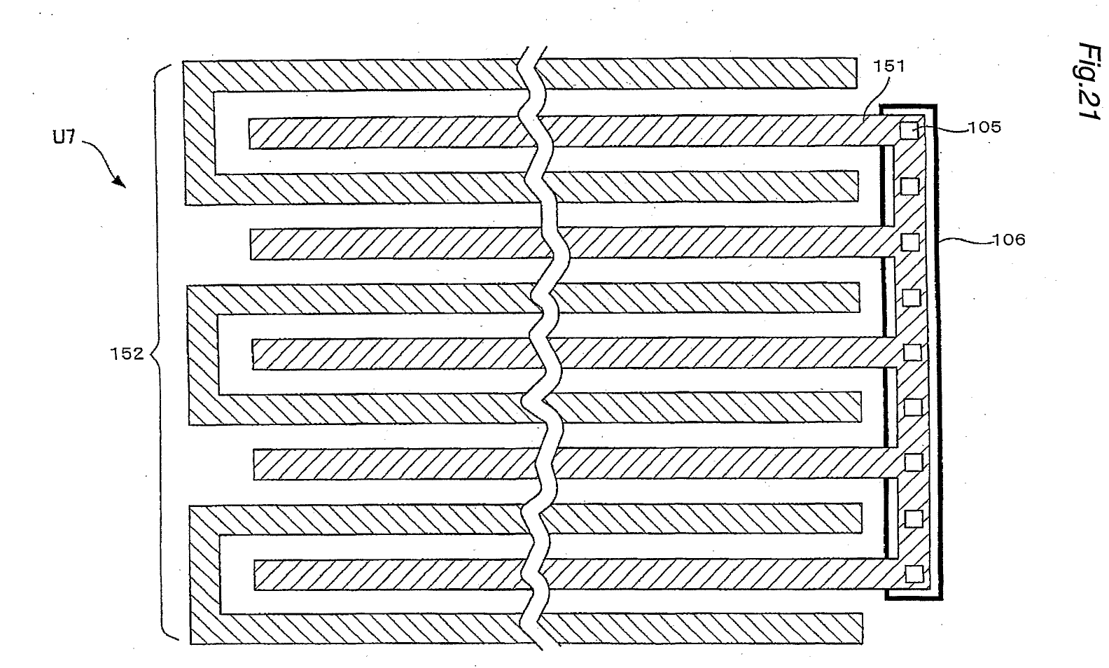

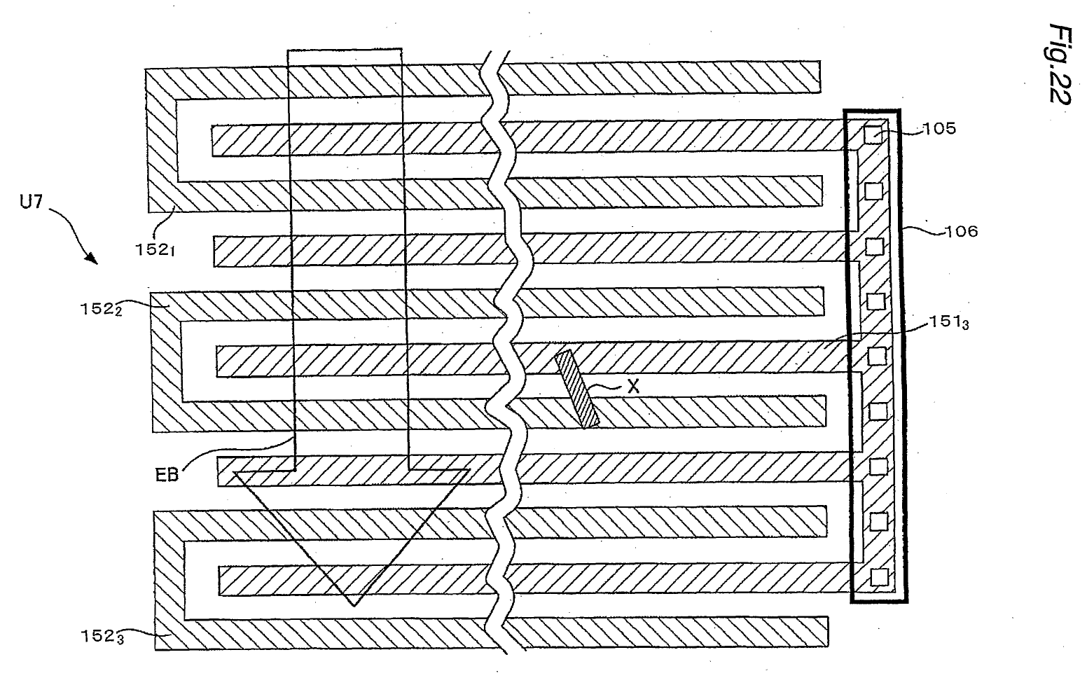

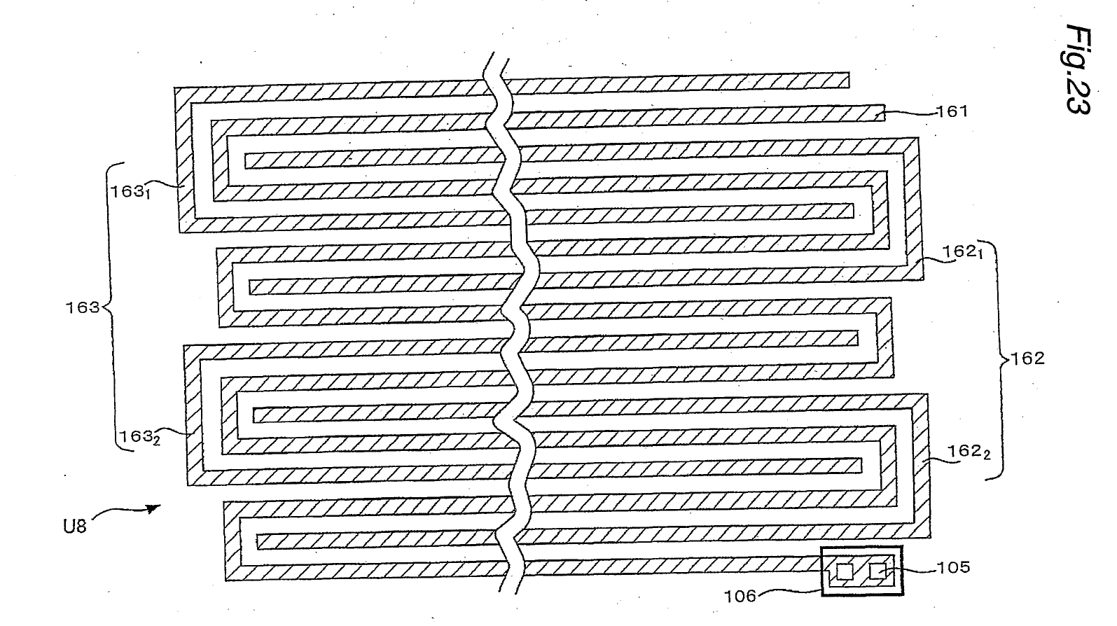

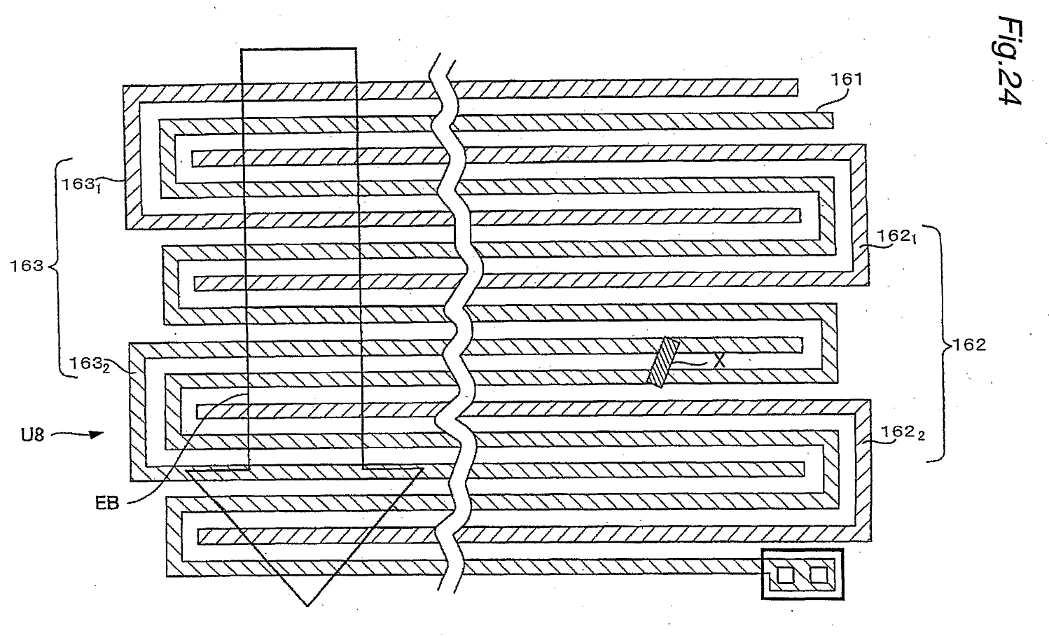

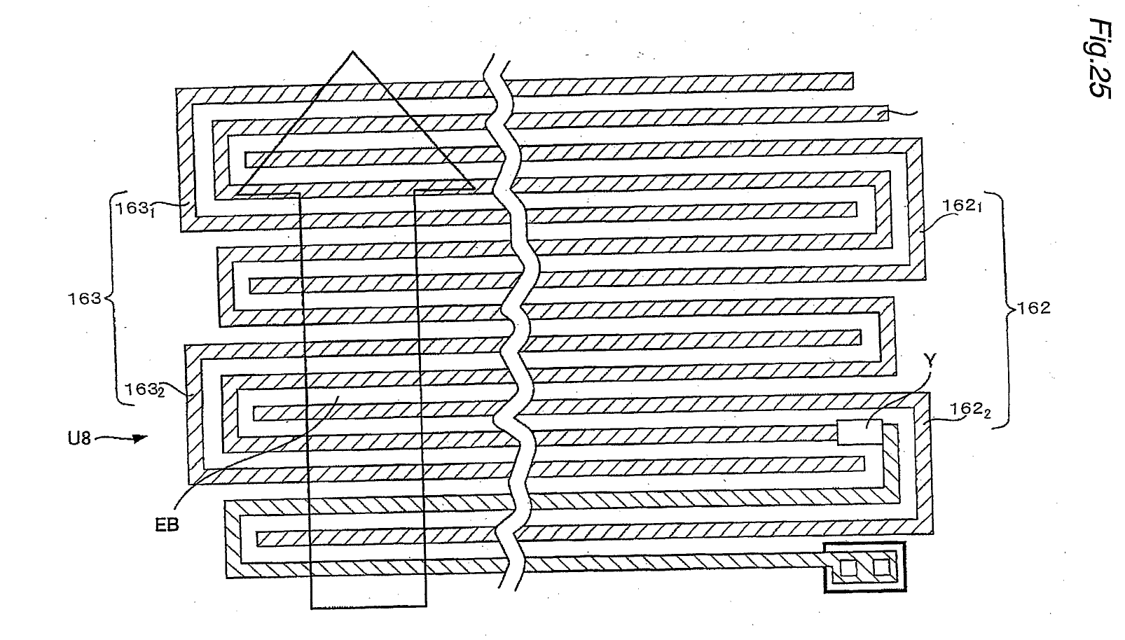

It is an eleventh embodiment illustrated in FIG. 20 that improves this disadvantage, and is characterized by maximizing the efficiency of detecting a short. In FIG. 20, a basic wiring pattern U6 is used for detecting both open and short, and the basic wiring pattern U6 comprises a first zig-zag wire 141, a second E-shaped wire 142 interdigitally arranged with respect to the first wire, and a third wire 143 having interdigital conductors which enter between opposing interdigital conductors of the first wire 141. With this structure, as illustrated, the interdigital conductor of the second wire or third wire intervenes between a pair of opposing interdigital conductors of the first wire 141. Thus, the basic wiring pattern U6 presents a higher short detection efficiency, as compared with the basic wiring pattern U5.

Likewise, in the embodiments illustrated in FIG. 17, FIGS. 18(A) and 18(B), FIG. 19(A), and FIG. 20, the pixel size required for a tester used for testing the basic wiring pattern can take a minimum value which is equal to the wiring pitch, and a maximum value which is equal to the size of the basic wiring pattern along a scanning direction for a test, as is the case with the description given in FIGS. 15 and 16.

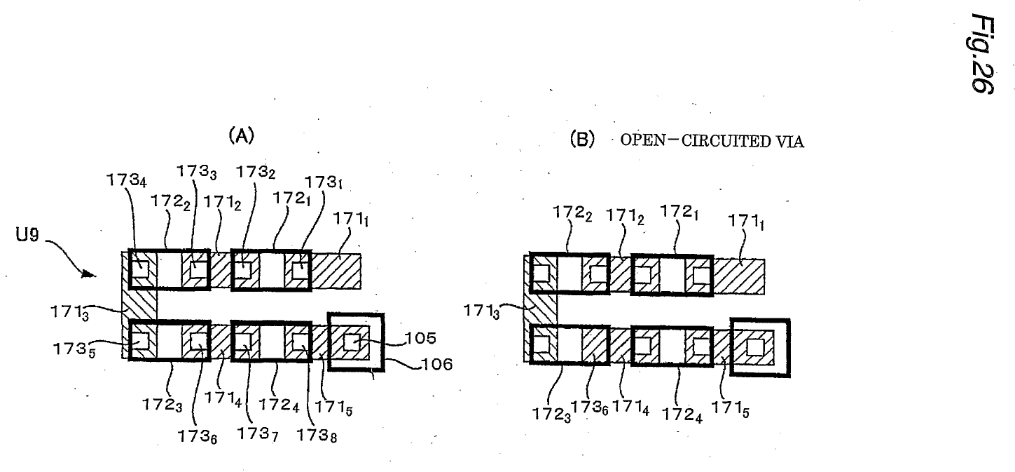

FIG. 21 is a diagram generally illustrating a basic wiring pattern in a twelfth embodiment of a semiconductor device according to the present invention, showing a basic wiring pattern which is improved from the conventional example illustrated in FIG. 1. The basic wiring pattern U7 in this embodiment is intended to detect a wire short, and comprises a first wire 151 which has a plurality of parallel interdigital conductors. Each of the interdigital conductors has one end connected to an active area 106 in a lower layer through a contact 105, and the first wire 151 is at the ground potential. Further, the basic wiring pattern U7 comprises a second wire 152 composed of a plurality of inverted C-shaped conductors, each made up of a pair of adjacent conductors of those conductors arranged in a line and alternately with the interdigital conductors of the first wire 151, and a conductor which connects ends of the paired conductors. The plurality of inverted C-shaped conductors of the second wire 152 are all at the floating potential.

In the conventional example illustrated in FIG. 1, any conductor at the floating potential is in a single linear shape, but when the structure is modified too connect each pair of conductors at the floating potential, the voltage contrast changes in a wider area when a short occurs, thus facilitating the detection of the short. This will be described in connection with an example illustrated in FIG. 22. FIG. 22 shows a direction in which an electron beam is scanned in order to detect a short-circuit failure in a shorter time, and a change in voltage contrast when a short occurs. Assume now that a foreign substance X causes a short between one interdigital conductor 151₃ of the first wire 151 and the inverted C-shaped conductor 152₂ which sandwiches the interdigital conductor in between. Then, the conductors 152₁, 152₃ of the second wire 152 remain at the floating potential, whereas the conductor 152₂ transitions to the ground potential. Subsequently, as one side of the basic wiring pattern U7 is scanned using an electron beam EB in a direction perpendicular to the interdigital conductors, a difference in potential difference resulting from a difference in potential between the conductors 152₁, 152₃ and conductor 152₂ can be confirmed in a wider area than the conventional example illustrated in FIG. 1.

Stated another way, from a viewpoint of a change in voltage contrast, a light/dark pattern changes only in a conductor (at the floating potential) in which a short has occurred in the conventional structure of FIG. 1, whereas by using the basic wiring pattern U7 illustrated in FIG. 21, a light/dark pattern changes in an increased number of conductors when a short occurs, and as a result, a change in a voltage contrast signal can be made in a wider area, thus making it possible to improve the detection sensitivity and detection speed. Also, when each conductor of the basic wiring pattern U7 is made sufficiently long, it is possible to identify a conductor in which a short has occurred even by scanning only those parts which connect parallel conductors of the second wire 152.

In the twelfth embodiment, two each of adjacent conductors at the floating potential are connected to form an inverted C-shape, but alternatively three or four adjacent conductors may be connected together to make interdigital conductors. In doing so, a larger voltage contrast signal, i.e., a larger change in light/dark pattern can be produced, thus making it possible to conduct a test with a larger pixel size to reduce a testing time.

FIG. 23 is a diagram generally illustrating a basic wiring pattern in a thirteenth embodiment of a semiconductor device according to the present invention, where the basic wiring pattern U8 is used for detecting both short and open. The basic wiring pattern U8 has a combined structure of a first wire 161 at the ground potential and a second wire 162 at the floating potential with a third wire 163 at the floating potential. The first wire 161 is formed in a zig-zag shape, and has one end connected to an active area 106 in a lower layer through a contact 105. The second wire 162 comprises a plurality of inverted C-shaped wires 162₁, 162₂, each having a pair of conductors extending between opposing conductor portions of the first wire 161 in one direction (from right to left in FIG. 23). Likewise, the third wire 163 comprises a plurality of inverted C-shaped wires 163₁, 163₂, each having a pair of conductors extending between opposing conductor portions of the first wire 161 in the direction (from left to right in FIG. 23) opposite to the one direction.

Now, assuming that a short is caused by a foreign substance X between the first wire 161 at the ground potential and the third wire 163 at the floating potential as illustrated in FIG. 24, the second wire 162 and the wire 163₁ of the third wire 163 remain at the floating potential, whereas the wire 163₂ of the third wire 163 transitions to the ground potential. As a result, when one side of the basic wiring pattern U8 is scanned using an electron beam EB, an increase in the wires at the ground potential results in a voltage contrast different from a voltage contrast in a normal state, which appears as a large change in contrast.

In another case, where an open occurs at an intermediate location Y of the first wire 161 as illustrated in FIG. 25, the wire on one side of the location Y at which the open has occurred transitions to the floating potential, so that when the basic wiring pattern U8 is scanned using an electron beam EB, a voltage contrast signal generated from the first wire 161 is different from and larger than that in a normal state, thus making it possible to readily detect the occurrence of an open.

For reference, a minimum spatial resolution of a tester for use in testing the basic wiring patterns U7, U8 in the embodiments illustrated in FIGS. 21 and 23 is the wiring pitch, i.e., the sum of the width of the conductors and the distance between the conductors. A maximum spatial resolution, in turn, may be comparable to the size of the basic wiring pattern in the scanning direction of the electron beam EB, or comparable to the size of the same pattern which appears in the scanning direction of the electron beam EB, depending on the size of the basic wiring pattern.

FIG. 26(A) is a diagram generally illustrating a basic wiring pattern in a fourteenth embodiment of a semiconductor device according to the present invention, where the basic wiring pattern U9 is similar to the inverted C-shaped basic wiring pattern illustrated in FIG. 18(A). The basic wiring pattern U9 comprises a plurality of conductors 171₁-171₅ formed in a first layer of a substrate (not shown); conductors 172₁-172₄ formed in a second layer of the substrate; and a plurality of vias 173₁-173₈ for connecting these conductors.

Describing further the structure of the basic wiring pattern U9 in greater detail, the plurality of conductors 171₁-171₅ are arranged in the first layer at predetermined intervals so as to form an inverted C-shape, and adjacent ends of adjacent conductors 171₁, 171₂ are connected to the conductor 172₁ in the second layer through the vias 173₁, 173₂, respectively. Subsequently, in a similar manner, adjacent ends of the conductors 171₂-171₅ in the first layer are connected to the corresponding conductors 172₂-172₄ in the second layer through the vias 173₃-173₈. The conductor 171₅ at one end is connected to an active area 106 in the second layer through a contact 105. In other words, the basic wiring pattern U9 is structured such that a predetermined number of via chain features are coupled, where the via chain structure is made up of adjacent conductors in the first layer, and one conductor in the second layer connected to the adjacent conductors through vias.

Assume now that a conduction failure occurs in some via, for example, the via 173₆ in the basic wiring pattern U9, as illustrated in FIG. 26(B), the conductors 171₄, 171₅ in the first layer, and the conductor 172₄ in the second layer remain at the ground potential, but the remaining conductors 171₁-171₃, 172₁-172₃ transition to the floating potential. This causes a change in voltage contrast starting from the non-conducting via, so that the non-conducting via can be detected.

For reference, a minimum spatial resolution of a tester for use in testing the basic wiring pattern U9 having the structure illustrated in FIG. 26 is equal to the wiring pitch, as is the case with FIG. 15, and a maximum spatial resolution can be comparable to the size of the basic wiring pattern U9, as is the case with FIG. 16.

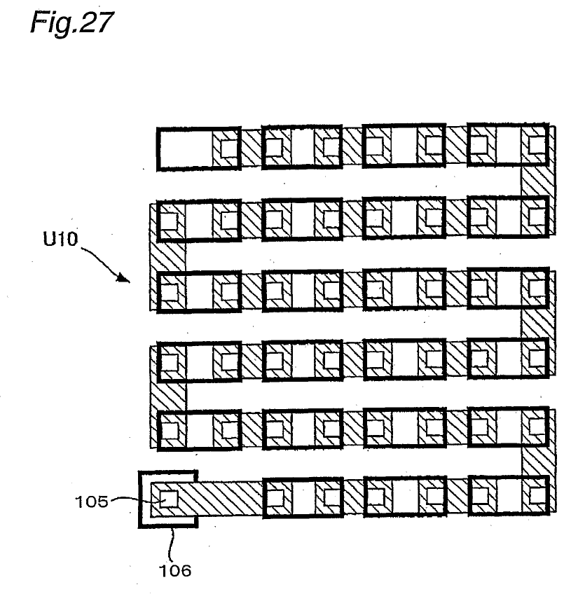

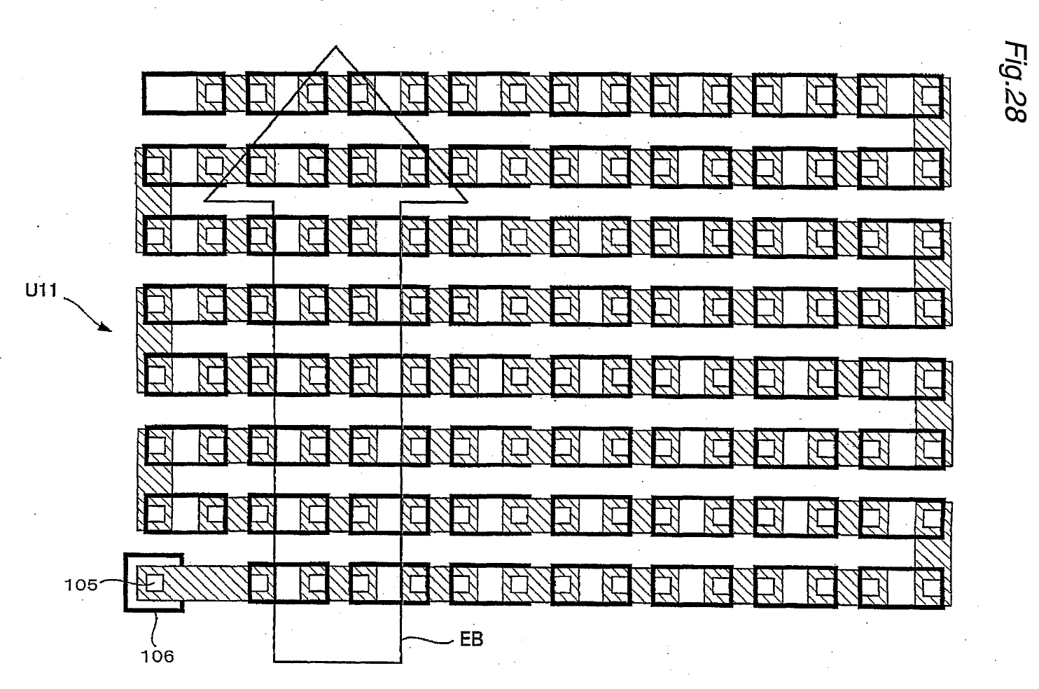

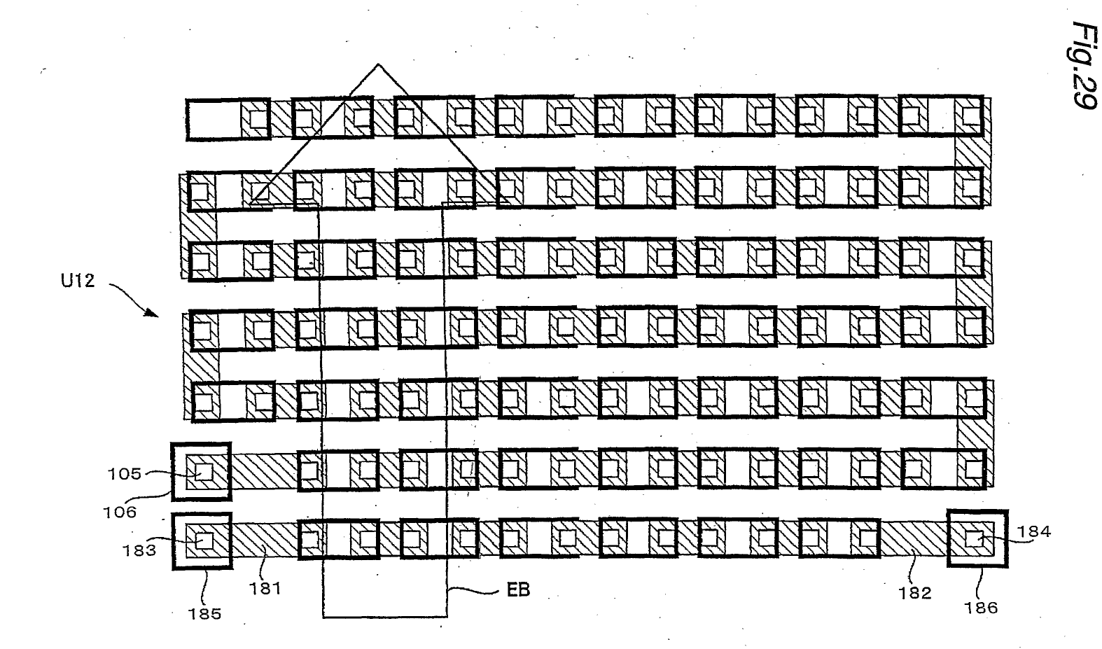

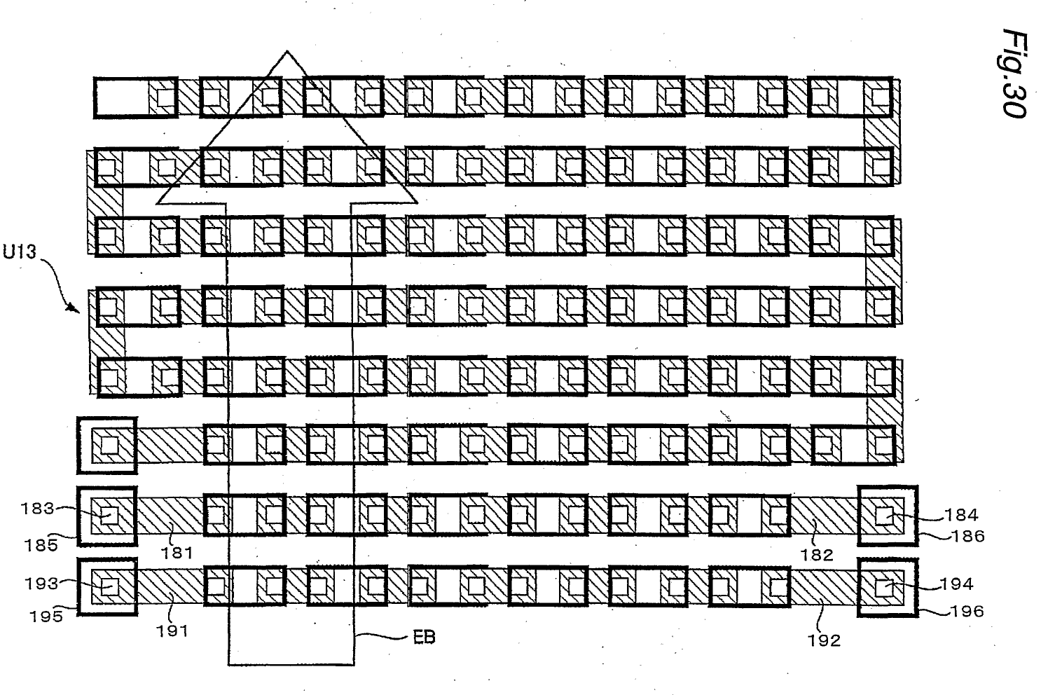

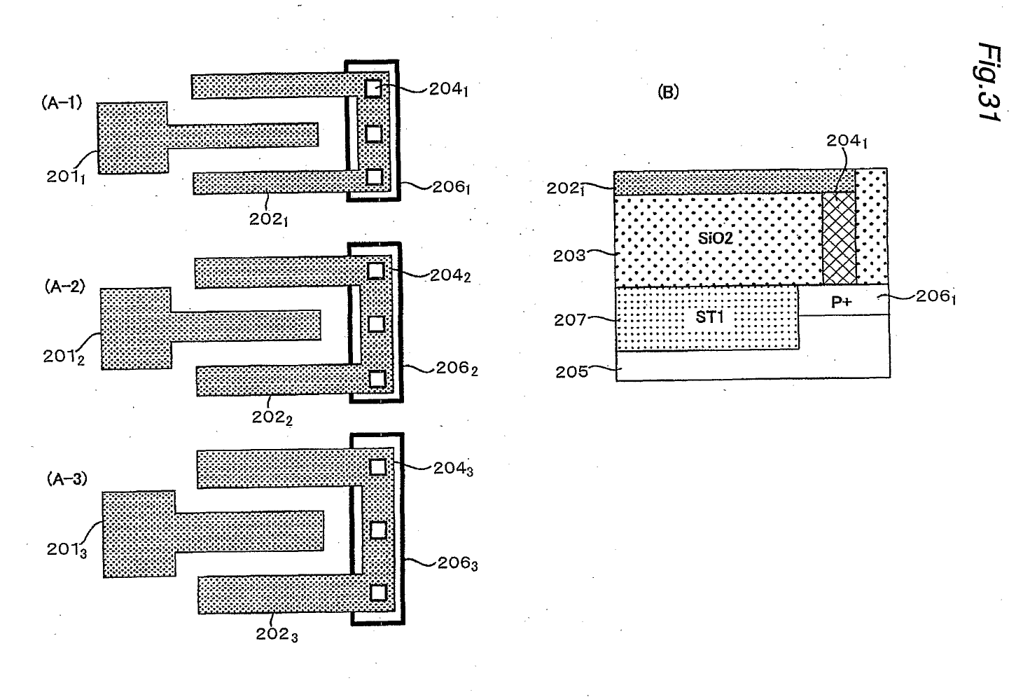

By increasing the length or number of the via chains in the basic wiring pattern U9, a yet larger basic wiring pattern can be created, where a large number of the via chain features are arranged in a zig-zag shape. FIG. 27 illustrates a basic wiring pattern U10 as one example thereof. Further, as illustrated in FIG. 28, the basic wiring pattern U10 illustrated in FIG. 27 can be further increased in size to create a basic wiring pattern U11.

With the basic wiring pattern U11 illustrated in FIG. 28, if a so-called array test is conducted, the voltage contrast reverses before and after an opened via, but it is difficult to determine which is normal and which is defective. However, when the basic wiring pattern U11 is scanned using an electron beam EB from a row including a conductor connected to the active area 106 of the substrate through the contact 105 (from the bottom to the top in FIG. 28), the defective via is detected without fail on that row or a conductor of another row (at a later time), so that it is possible to identify which side is defective. However, if a defective via exists in a row including a conductor connected to the active area 106, the lowermost voltage contrast signal becomes shorter, possibly causing an inconvenience in regard to the detection.

FIG. 29 is a diagram generally illustrating a basic wiring pattern in a fifteenth embodiment of a semiconductor device according to the present invention, which is proposed to eliminate the inconvenience when a defective via exists in the lowermost stage. The basic wiring pattern U12 of this embodiment comprises a reference row having a via chain feature similar to, and adjacent to the row including the conductor connected to the active area 106 in the basic wiring pattern U11 illustrated in FIG. 28. Conductors 181, 182 in a first layer, positioned at both ends of the reference row, have their both ends connected to active areas 185, 186 through contacts 183, 184, respectively, and are set to the ground potential. Therefore, even if any via becomes non-conductive between the conductors 181, 182 at both ends of the reference row, all the conductors of that row are maintained at the ground potential, so that the voltage contrast does not change to cause the inconvenience in regard to the detection.

FIG. 30 illustrates a basic wiring pattern U13 which is intended to produce similar effects to those of the fifteenth embodiment illustrated in FIG. 29. The basic reference pattern illustrated in FIG. 30 comprises a second reference row adjacent to the reference row in the basic wiring pattern U12 of FIG. 29, where in the second reference row, conductors 191, 192 at both ends are connected to active areas 195, 196 through contacts 193, 194, respectively, and are grounded. With this structure, like the basic wiring pattern U12 illustrated in FIG. 29, even if a conduction failure occurs in any via of the second reference row, all the conductors of that row are maintained at the ground potential, so that the voltage contrast does not change. In other words, irrespective of the presence or absence of a conduction failure of a via, the reference rows function as stable references.

The reference row is not limited to one or two, but there may be three or more reference rows. The number of reference rows is desirably set such that the whole number of rows in the reference wiring pattern U12, U13, including the reference rows, is equal to n times (where n is a positive integer) as large as the size of pixels used in the test.

In the basic wiring patterns U10-U13 illustrated in FIGS. 27-30, the minimum pixel size for a tester used for confirming the presence or absence of non-conducting vias is equal to the wiring pitch, but the entire basic wiring pattern U10-U13 may be scanned depending on the size of the basic wiring pattern, or only one side of the basic wiring pattern U10-U13 may be scanned in order to reduce a scanning time. In other words, the maximum pixel size for the tester may be comparable to the size of the basic wiring pattern in the scanning direction of the electron beam EB, or may be comparable to the size of the same pattern as the basic wiring pattern appearing in the scanning direction of the electron beam EB. If a non-conducting via is found in part of the basic wiring pattern, a change in potential appears on one side of this via, resulting in a different voltage contrast from the normal voltage contrast.

Alternatively, the basic wiring patterns illustrated in FIGS. 17, 18(A), 19(A), 20, 21 and 23 may be arranged in a matrix of m rows and n columns, as illustrated in FIGS. 13 and 14.

By the way, for knowing a structural dimensional margin from a view point of short-circuit resistance, the basic pattern illustrated in FIG. 1 may be developed to arrange a plurality of test element groups (hereinafter called the “TEG”) which differ in line width and wiring space, and a short-circuit yield rate is measured on a TEG-by-TEG basis by a VC test using an electron beam to examine a margin. Likewise, for knowing a line break resistance margin of wires, and a conduction failure resistance margin of contacts and vias, a plurality of TEG's, which have different dimensions of interest, are arranged in a line and subjected to the VC test for detection. Embodiments based on such findings will be described below. These embodiments have been proposed on the basis of findings that by arranging two types of wires at different potentials alternately in a predetermined direction, a short-circuit failure between wires causes a change in the potential on the wires, and an image generated in the VC test differs from a normal image, thereby making it possible to know where the short-circuit failure has occurred.

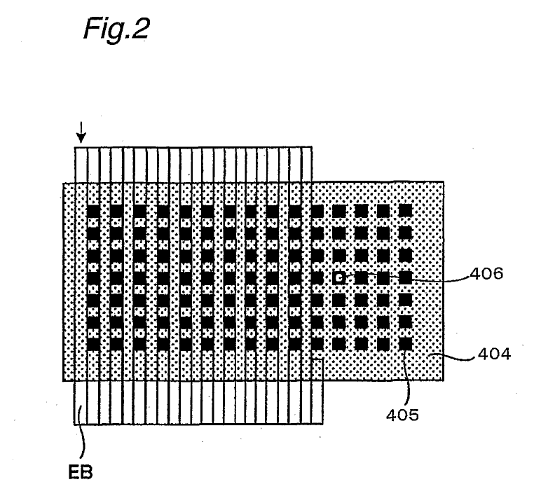

FIGS. 31(A-1)-31(A-3) generally illustrates a basic pattern and structure in a sixteenth embodiment of a semiconductor device according to the present invention, generally showing a pattern shape of a test element group (hereinafter called the “TEG”) for wire short-circuit detection in order to measure a short-circuit resistance dimensional margin, and FIG. 31(B) is a cross-sectional view of one TEG. FIGS. 31(A-1)-31(A-3) are illustrated on the same plane irrespective of in which layer of semiconductor each component is formed, in order to describe positional relationship among components in three types of TEG's which differ in pattern shape. In FIG. 31, the TEG's, the structure of which is illustrated in (A-1)-(A-3), are formed, for example, on the same die (or chip) on the same semiconductor device to create one group of TEG's. Any TEG comprises first wires 201₁, 201₂, 201₃ at the floating potential; and second inverted C-shaped wires 202₁, 202₂, 202₃, at the ground potential, which are arranged to surround three sides of the first wires. As illustrated in FIG. 31(B), the first wire 201₁ and second wire 202₁ are formed on the top surface of an SiO₂ layer 203 to make up a first layer, and the second wire 202₁ is connected to an active area 206₁ in a second layer formed on a substrate 205 through a plurality of contacts 204₁ which extend through the SiO₂ layer 203. Reference numeral 207 designates an STI (shallow trench isolation) layer. Such a structure is similar in the TEG's illustrated in FIGS. 31(A-2) and 31(A-3), where 2042, 2043 designate contacts, and 206₂, 206₃ designate active areas.

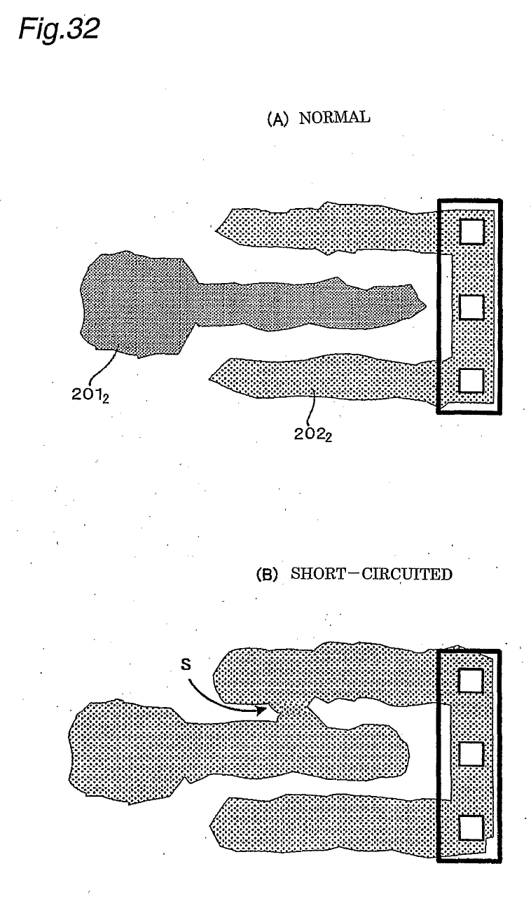

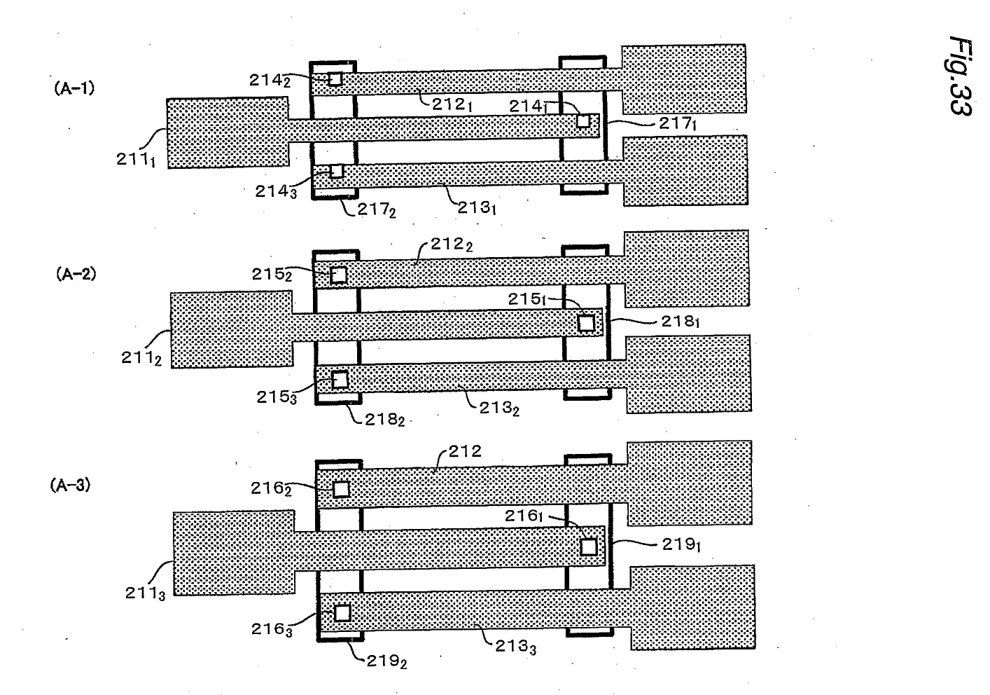

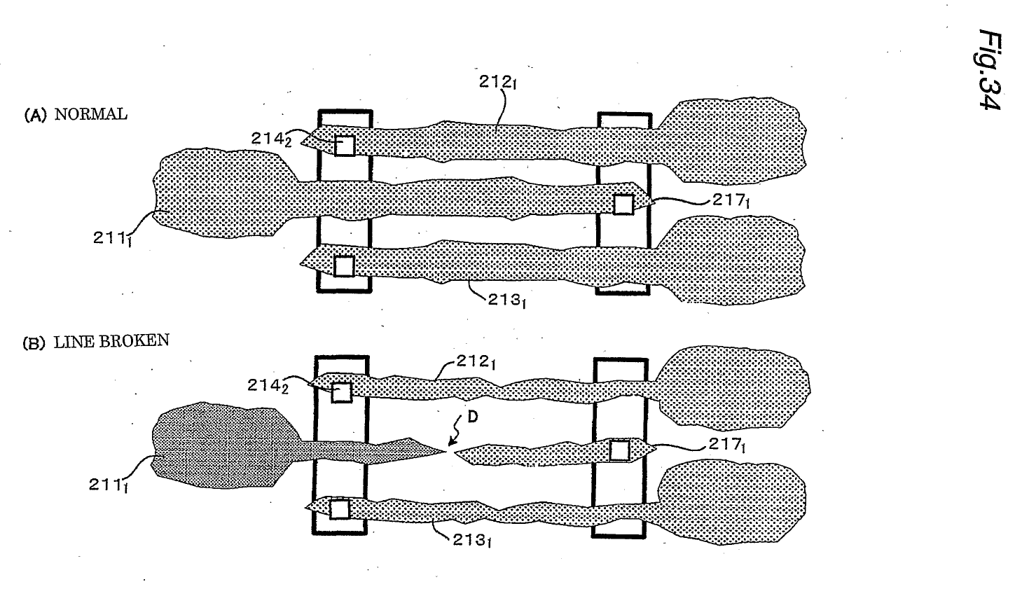

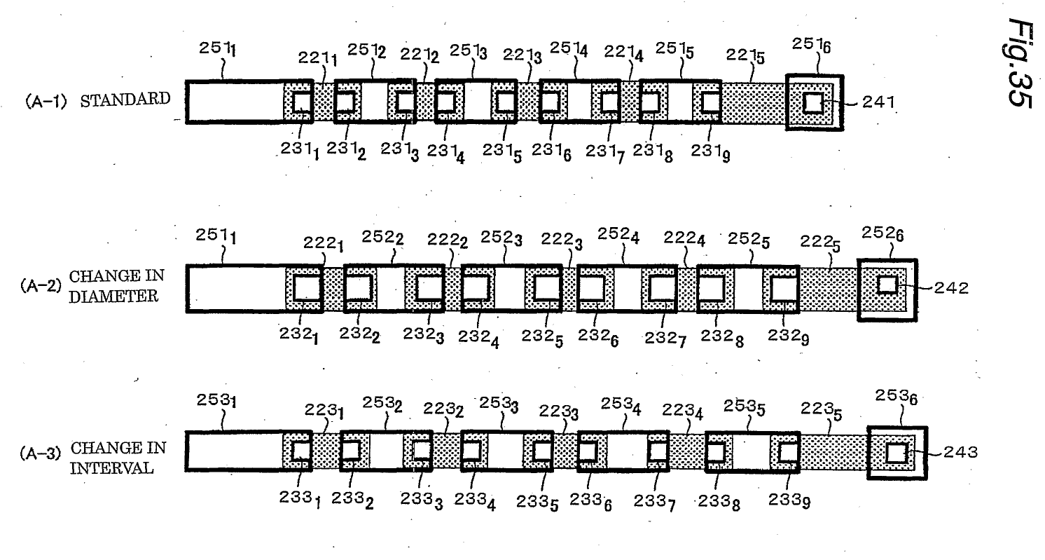

As is apparent from FIGS. 31(A-1)-31(A-3), these three types of TEG's basically have the same structure except that the first wire and second wire differ in line width from one another. As such, the TEG illustrated in FIG. 31(A-2), for example, is irradiated with an electron beam to generate an image of secondary electrons emitted therefrom. Exemplary images are shown in FIGS. 32(A) and 32(B). FIG. 32(A) shows an image which is generated when there is no short-circuited location in the TEG, where a large amount of secondary electrons are emitted from the grounded second wires 202₂, resulting in a light secondary electron image, while a small amount of secondary electrons is emitted from the first wire 201₂ located in between, thus resulting in a dark secondary electron image. On the other hand, FIG. 32(B) shows an image when an electrically short-circuited location S exists in the TEG, where the first wire 201₂, which should be essentially at the floating potential, is at the ground potential, so that the entire TEG creates a light secondary electron image. Applying this principle to the TEG's illustrated in FIGS. 31(A-1)-31(A-3), it can be known in a TEG of which dimension a short-circuit failure will occur. In this way, it is possible to known a dimensional area width for preventing a short-circuit failure, i.e., a dimensional margin.

FIGS. 33(A-1)-33(A-3) are diagrams generally illustrating basic patterns and structures in a seventeenth embodiment of a semiconductor device according to the present invention, where the diagrams generally illustrate the structures of TEG's for wire break detection in order to measure a break margin, and show a positional relationship among respective components, when the semiconductor device is viewed from above. Similar to the sixteenth embodiment, the TEG's illustrated in FIGS. 33(A-1)-33(A-3) are also formed on the same semiconductor device to create one TEG group, which has a pattern, where second wires 212₁, 212₂, 212₃ are arranged on one side of first wires 211₁, 211₂, 211₃ in parallel with these first wires, and third wires 213₁, 213₂, 213₃ are arranged on the other side of the first wires 211₁, 211₂, 211₃ in parallel with these first wires. Likewise, in this seventeenth embodiment, the first-third wires are similar in shape from one another, like the sixteenth embodiment illustrated in FIG. 13, but they differ in that the first wire has the smallest line width, the third wire has the largest line width, and the second wire has a line width which is intermediate between them.

Further, the right-hand ends of the first wires 211₁, 211₂, 211₃, as viewed from the front of FIG. 3, are connected to active areas 217₁, 218₁, 219₁ through contacts 214₁, 215₁, 216₁, respectively. The left-hand ends of the second wires 212₁, 212₂, 212₃, as viewed from front of FIG. 33, are connected to active areas 217₂, 2218₂, 219₂ through contacts 214₂, 215₂, 216₂, respectively, and the left-hand ends of the third wires 213₁, 213₂, 213₃, as viewed from the front of FIG. 33, are connected to active areas 217₂, 218₂, 219₂ through contacts 214₃, 215₃, 216₃, respectively. Accordingly, the first to third wires are all at the ground potential in a normal state.

Then, when the TEG illustrated in FIG. 33(A-1), for example, is irradiated with an electron beam to generate an image of secondary electrons emitted therefrom, a resulting secondary electron image is light, as illustrated in FIG. 34(A), when the TEG is normal, because all the first to third wires are at the ground potential, and a large amount of secondary electrons are emitted from these grounded wires. On the other hand, if the first wire 211₁, for example, is broken in the middle at any location, a right-hand section of the first wire, as viewed from the front of the figure, remains at the ground potential, whereas the left-hand section transitions to a floating state. For this reason, as shown in FIG. 34(B), a light secondary electron image is generated because a large amount of secondary electrons are emitted from the right-hand section from a location corresponding to the broken location D of the first wire 211₁, whereas a dark secondary electron image is generated because a small amount of secondary electrons are emitted from the left-hand section. By using this principle, it is possible to know whether or not a line break failure will occur from a wire of a particular line width, and hence know a range of line widths which do not give rise to a line break failure, i.e., a break resistance dimensional margin.

Though not shown, in the seventeenth embodiment, either of the first wires 211₁-211₃, second wires 212₁-212₃, and third wires 213₁-213₃ are also formed on the top surface of an SiO₂ layer, and the active areas 217₁-217₂ are formed on the bottom surface of the SiO₂ layer and the top surface of the substrate 205. Also, in the seventeenth embodiment, one of the second wires 212₁-212₃ and third wires 213₁-213₃ may be omitted.

Next, FIGS. 35(A-1), 35(A-2) and 35(A-3) are diagrams generally illustrating basic patterns and structures in an eighteenth embodiment of a semiconductor device according to the present invention, generally illustrating the structures of TEG's for measuring a conduction failure margin of vias or contacts. In this eighteenth embodiment, a first TEG illustrated in FIG. 35(A-1) is a TEG having standard size; a second TEG illustrated in FIG. 35(A-2) is changed in the diameter of holes of the standard size; and a third TEG illustrated in FIG. 35(A-3) is changed in the spacing between holes. These TEG's are formed on the same semiconductor device to create one TEG group.

As illustrated in FIG. 35(A-1), the first TEG comprises a plurality of row wires 221₁, 221₂, 221₃, 221₄, 221₅ arranged in a first layer in a line at predetermined intervals in the row direction. These row wires have their ends connected to active areas 251₁-251₆ formed in a second layer through vias 231₁-31₉, having a predetermined hole diameter, or contacts 241. In the figure, only the right end of the rightmost row wire 221₅ is connected to the active area 251₆ through the contact 24₁.

The second TEG is similar to the first TEG except that the vias and contact have a larger diameter than those in the first TEG. Specifically, the second TEG comprises a plurality of row wires 222₁, 222₂, 222₃, 222₄, 222₅ arranged in the first layer in a line at predetermined intervals in the row direction, and these row wires have their ends connected to active areas 252₁-252₆ formed in the second layer through vias 232₁-232₉ or contact 242. In the figure, only the right end of the rightmost row wire 2225 is connected to the active area 252₆ through the contact 242.

The third TEG is similar to the first TEG except that the vias and contact are spaced apart by larger intervals from one another. Specifically, the third TEG comprises a plurality of row wires 223₁, 223₂, 223₃, 223₄, 223₅ arranged in the first layer in a line at predetermined hole intervals in the row direction, and these row wires have their ends connected to active areas 253₁-253₆ formed in the second layer through vias 233₁-233₉ of a predetermined hole diameter or a contact 243. In the figure, only the right end of the rightmost row wire 224₅ is connected to the active area 253₆ through the contact 243.

Now, in the eighteenth embodiment, it can be known in a manner similar to the sixteenth embodiment and seventeenth embodiment that in a hole or hole spacing of which dimension, a conduction failure will occur by irradiating the first to third TEG's with an electron beam, finding a light/dark pattern of a secondary electron image of each TEG by the VC method, and measuring whether the conduction is good or bad on a TEG-by-TEG basis. In this way, it is possible to know a conduction failure margin for the vias or contact.

As will be apparent from the description so far made, the TEG's are formed on the same die (or chip) in the sixteenth embodiment to eighteenth embodiment. For irradiating each TEG with an electron beam to generate a secondary electron image when a plurality of dies are formed on a wafer, the secondary electron images are generated at different pitches because the respective TEG's are different in size. There are a variety of methods for detecting secondary electron signals at different pitches, generated from the respective TEG's, and extracting sites of short, break, conduction failure and the like from these secondary electron signals. One of them is a method of comparing secondary electron signals generated from the same type of TEG's on adjacent dies with each other, and detecting a high or a low matching degree to extract a defective TEG or a defective site, i.e., a die comparison method. This method can compare TEG's at any wiring pitch independently of the wiring pitch of TEG's formed on dies, but has a problem, resulting from a large distance between adjacent dies, that secondary electron signals tend to differ in intensity among TEG's of the same type, formed on these dies, and that the detection sensitivity is inferior.

On the other hand, in a method of previously recognizing a wiring pitch of each TEG, and comparing this pitch with a pitch of a light/dark pattern derived from a secondary electron signal to detect anomaly of the light/dark pitch, i.e., a so-called cell detection method, this method is advantageous in that secondary electron signals are stable in intensity distribution, and the detection sensitivity is high because the comparison is made within a micro-area. However, with this cell detection method, if there are a plurality of TEG's which differ in pitch, the correct pitches of all TEG's must have previously been registered or automatically recognized. Anyway, all TEG's can be continuously tested at a high sensitivity, and a testing time can be largely reduced.

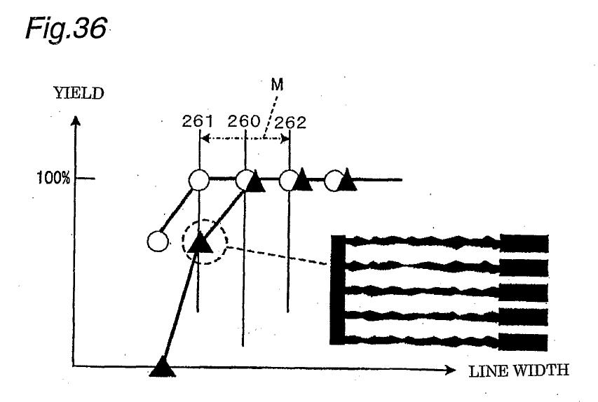

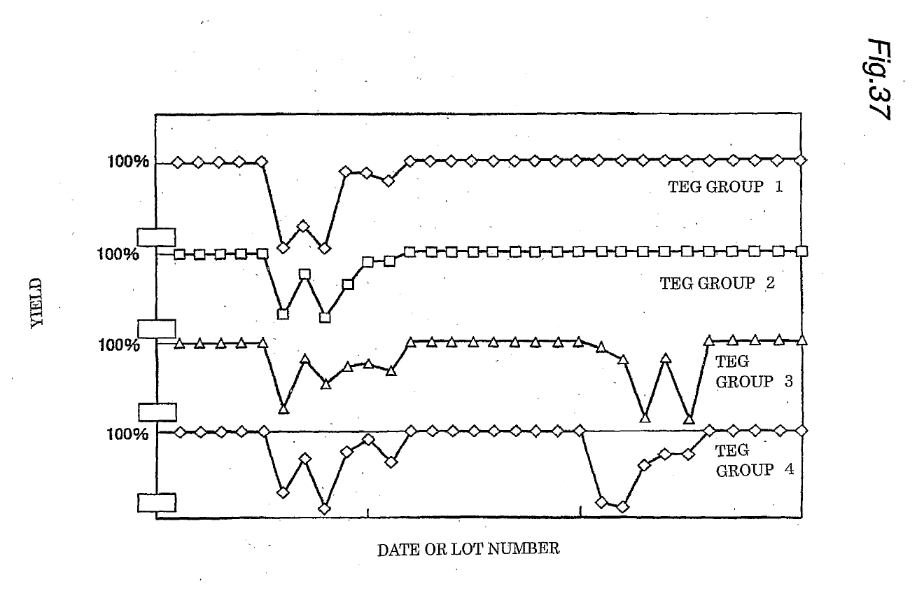

FIG. 36 is a graph showing the relationship between variations in line width of wire and the yield rate of each TEG, derived from a group of TEG's which comprise TEG's having similar functions to the TEG's illustrated in FIGS. 3(A-1)-3(A-3). As shown, the line width of wire is centered at a design center value 260, and includes a range from the vicinity of a design lower limit value 261 to the vicinity of a upper limit value 262. The range from the design lower limit value 261 to the design upper limit value 262 is allowable machining variations, i.e., an allowable margin M. Alternatively, the yield rate can be replaced with efficiency percentage or defective percentage.

It is understood from FIG. 36 that when a wafer manufacturing process is normal, the line width in TEG's falls under the range from the design lower limit value 261 to the design upper limit value 262, and a high yield rate is ensured. However, if a failure occurs in the manufacturing process, for example, a machining margin is insufficient, resulting in a decrease in the line width to a value close to the design lower limit value 261, the line width is reduced to make the dimensional margin insufficient for line break, leading to a lower yield rate, as shown. In other words, in FIG. 36, by monitoring the yield rate of TEG's of a variety of dimensions at all times, it is possible to immediately know that a failure has occurred in the manufacturing process, and by previously setting a threshold for the yield rate, semiconductor devices can be determined as defective if their yield rates are lower than the threshold. When the efficiency percentage or defective percentage are substituted for the yield rate, a lower limit value is set for the efficiency percentage, while an upper limit value is set for the defective percentage, in which case semiconductor devices are determined as defective if the defective percentage falls below the upper limit value, or the efficiency percentage exceeds the lower limit value.

FIG. 37 is a graph which records variations in the yield rate of a representatives TEG selected from each of four different TEG groups formed on a single die, together with the date or lot number of the die. By appropriately selecting the respective TEG groups, it can be known from this graph in which manufacturing process a failure has occurred. The representative TEG in each TEG group is preferably a TEG which has a wire width near the design lower limit value, which is more likely to degrade the yield rate due to a failure in the manufacturing process.

In the sixteenth to eighteenth embodiments so far described, a plurality of TEG's having the same pattern shape may be provided.

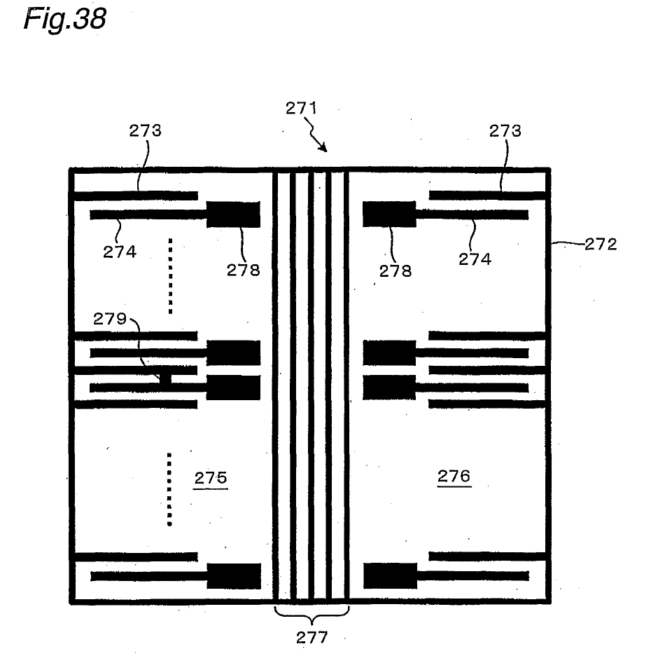

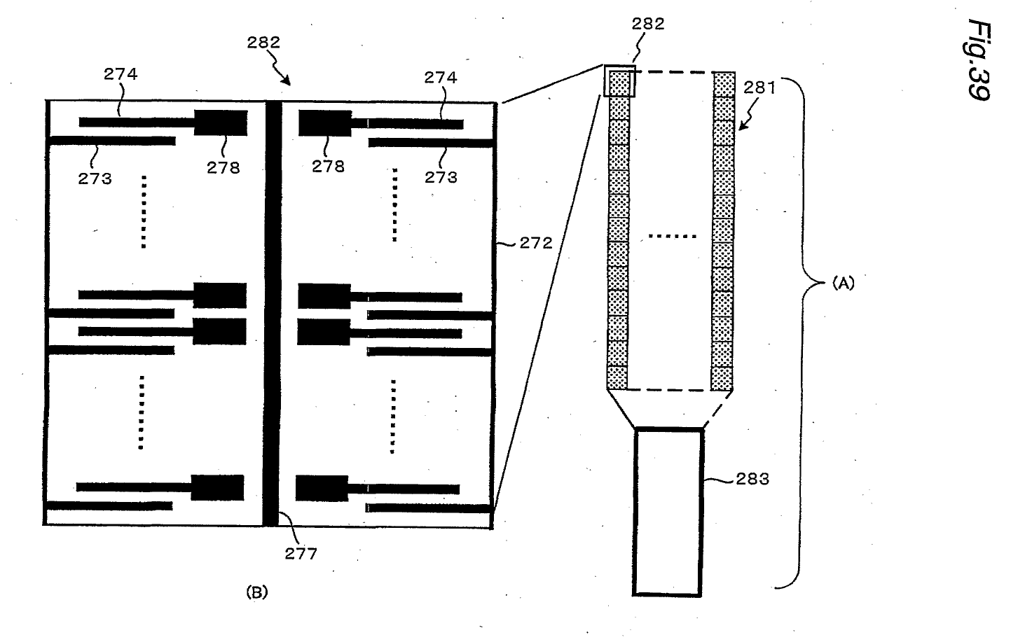

FIG. 38 is a diagram generally illustrating a nineteenth embodiment of a semiconductor device according to the present invention, where this semiconductor device comprises a TEG formed by arranging a large number of wires of two types in alternate order or in bilateral symmetry. As illustrated, the TEG 271, the periphery of which is surrounded by a TEG frame 272 which is a grounded wire, comprises two TEG areas 275, 276 in which wires 273 connected to the TEG frame 272 and therefore placed at the ground potential, and wires 274 at the floating potential are arranged in alternate order and in parallel. Further, a wire 277 at the ground potential is arranged in a direction perpendicular to the wires 273, 274 between the two TEG areas 275, 276. The two TEG areas 275, 276 are arranged in bilateral symmetry with respect to the wire 277. The structure designed as described above produces an effect of preventing an electron beam, irradiated to the TEG 271, from impinging out of the area of the TEG 271 and the irradiated portion from being charged up.

As illustrated, the wire 274 at the floating potential is in a shape which has a pad structure 278 having an expanded end near the center of the TEG 271. This pad structure 278 is provided for emphasizing a change in a light/dark pattern in an image which is captured by a VT test when the wire 274 at the floating potential shorts with the adjacent wire 273 at the ground potential at any location (for example, a short occurs at a location indicated by a numeral 274 in FIG. 38). In this way, a large number of pad structures 278, at the floating potential, are provided in a central region of the TEG 271, which causes the entire central region to readily transition to the floating potential, so that the wires 277 at the ground potential are arranged in the central region, which is a structure employed with the intention to stabilize the potential in the central region.

FIG. 39 is a diagram generally illustrating a twentieth embodiment of a semiconductor device according to the present invention, showing a TEG 281 in which the TEG's 271 in a laterally symmetric shape, as illustrated in FIG. 38, are two-dimensionally arranged. The TEG 281 illustrated in FIG. 39(A) has a structure based on a TEG 282, having a structure similar to the TEG 271 illustrated in FIG. 38, in which a large number of TEG's 282 are arranged in columns and rows, and the periphery of the TEG 281 is surrounded by a TEG frame 283. Stated another way, the TEG 281 illustrated in FIG. 39 has the TEG frame 283 larger than that of the TEG 281 illustrated in FIG. 38, and the TEG's 282 having the basic structure illustrated in FIG. 39(B) are arranged in columns and rows within the TEG 283.

Therefore, for testing the TEG 281 illustrated in FIG. 39, it is possible to scan the TEG 281 in small widths using an electron beam of a sufficiently small pixel size from the beginning such that a location at which a failure has occurred can be detected in detail. However, this can require an immense testing time. Therefore, in order to reduce the testing time, an electron beam is irradiated for conducting a test with a large pixel, i.e., in wide scanning widths at the first time, and a TEG area in which a short-circuit failure has occurred may be previously ascertained in general, for example, in units of minimum TEG widths in the first test, and in the second test, only the TEG area in which the short-circuit failure has occurred may be tested with a smaller pixel size in smaller scanning widths. In this event, the scanning width in the second test should be set to an integer multiple of the scanning width in the first test, a multiple of two, or a multiple of two's power, because the scanning width in the second test falls within the scanning width in the first test, neither too much or too little, so that the test efficiency can be increased. Also, when the TEG is designed, the scanning width is preferably set such that no area is not scanned.

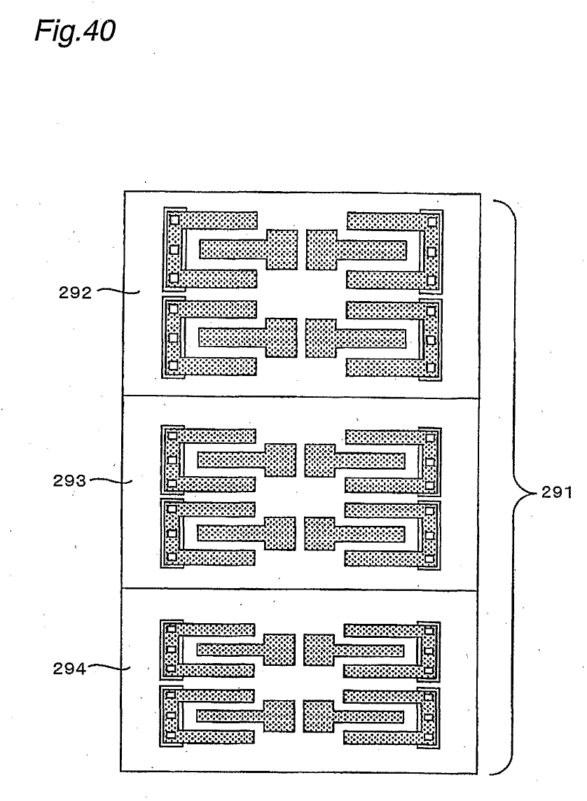

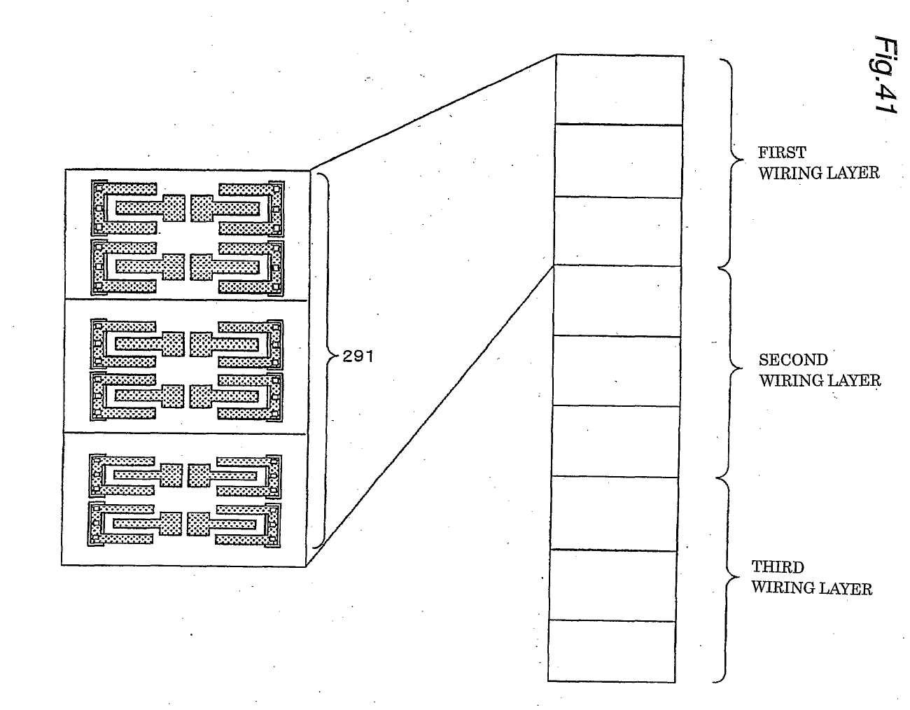

FIG. 40 is a diagram generally illustrating a twenty first embodiment of a semiconductor device according to the present invention, where this semiconductor has a TEG 291 which has a structure in which two pairs each of the three types of basic structure TEG's illustrated in FIGS. 31(A-1)-31(A-3) are arranged so as to oppose each other. Specifically, the TEG 291 comprises TEG's 292 having the largest line width; TEG's 293 having an intermediate line width; and TEG's 294 having the smallest line width. This TEG 291 is designed for purposes of examining a correlation of the line width to the occurrence of short-circuit failure, and it is generally thought that a larger line width is more susceptible to the short-circuit failure.

In the VC test using an electron beam, if there are many areas at the floating potential, the potential largely fluctuates near such areas on the surface of a semiconductor device to bend the electron beam for scanning, possibly exerting adverse influence on the result of the test. Specifically, if an area including many wires at the floating potential is positioned on the upstream side of electron irradiation, its adverse influence can be exerted on the downstream side. To avoid this problem in the least, in FIG. 40, the TEG area 292 having the largest line width, which is assumed to include relatively few areas at the floating potential, is positioned on the upstream side of electron irradiation.

In such a TEG for short-circuit failure detection, a pad structure 278 having a relatively large area is formed near a mirror symmetry axis of the TEG (for example, an axis passing the center line of a wire 277 in FIGS. 38 and 39) so as to emit many secondary electrons in response to the electron beam irradiation, and therefore so as to generate a large VC test signal. As such, only the vicinity of the pad structure 278 need be tested in order to detect whether or not a short-circuit failure is present in the TEG. For example, in FIG. 39, an electron beam need be irradiated only to an area which includes a wire 277 and pad structures on both sides thereof. In FIG. 40, in turn, only an area including pad structures positioned on both sides of a symmetry axis of each TEG areas 292-294 need be scanned using an electron beam for testing.

FIG. 41 is a diagram generally illustrating a twenty second embodiment of a semiconductor device according to the present invention, which is developed from the TEG 291 illustrated in FIG. 40. In FIG. 40, the TEG 291 is intended for a particular wiring layer. On the other hand, in the twenty second embodiment, the TEG's 291 illustrated in FIG. 40 are formed in different wiring layers (a first wiring layer—a third wiring layer in FIG. 41) at shifted positions such that they do not overlap one another. The TEG's are continuously disposed so as not to overlap one another in order to irradiate an electron beam only to an area in which the TEG is formed and not to irradiate the electron beam to unnecessary areas.

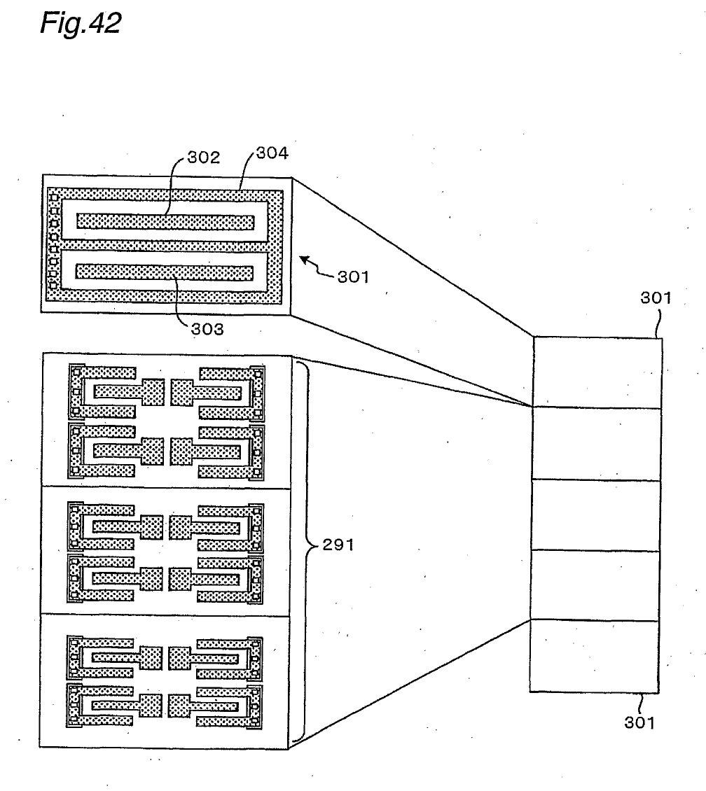

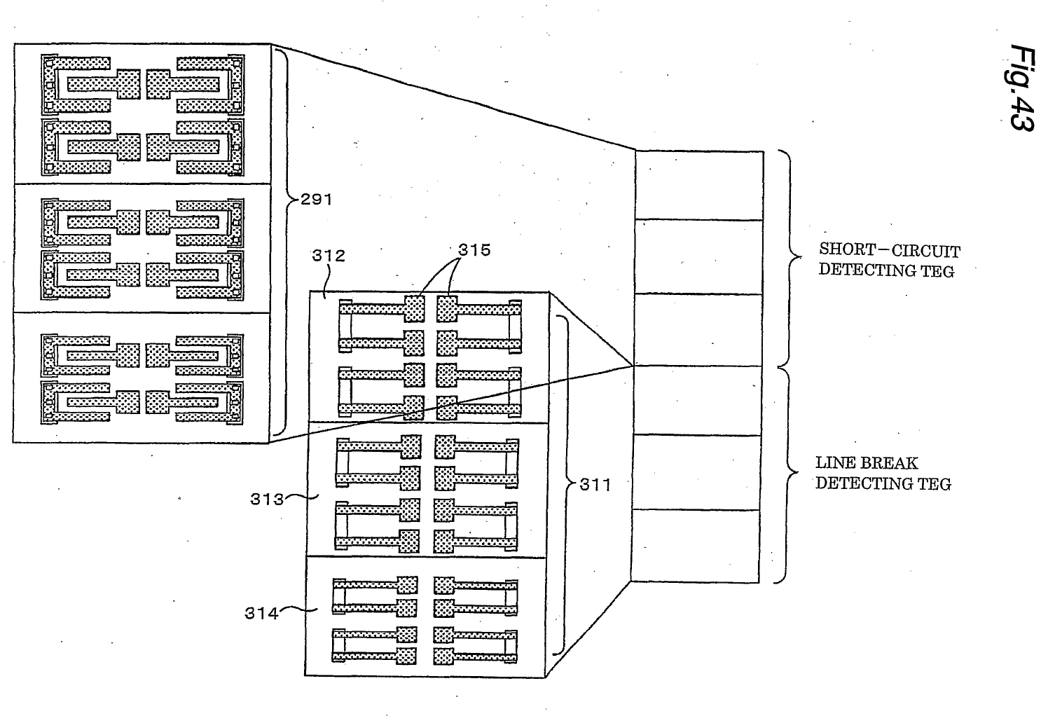

FIG. 42 generally illustrates a twenty third embodiment of a semiconductor device according to the present invention. In this embodiment, the TEG 291 illustrated in FIG. 30 is disposed in one wiring layer, and additionally disposed in the same wiring layer is a stable dummy TEG 301 which is not likely to suffer from a line break failure, on the upstream, or downstream, or upstream and downstream of the TEG 291, when viewed from a direction in which the electron beam is irradiated for scanning in the event of the VC test. As illustrated, the dummy TEG 301 comprises a pair of wires 302, 303 which are at the floating potential and arranged in parallel with each other, and a wire 304 at the ground potential, which is disposed to surround the periphery of these wires.

Since the semiconductor device comprises the dummy TEG 301 as described above, it is possible to avoid a problem, when an electron beam is irradiated for a VC test, that the electron beam is irradiated to an upstream and downstream area of the TEG 291 due to an insufficient positioning accuracy and the like to charge up areas other than the TEG 291.

FIG. 43 is a diagram generally illustrating a twenty fourth embodiment of a semiconductor device according to the present invention, where a TEG for short-circuit failure detection and a TEG for line break failure detection are disposed in a single wiring layer. As illustrated, the TEG 291 illustrated in FIG. 40 is used for the TEG for short-circuit failure detection, while a TEG 311 having a small pattern, which is less likely to suffer from a line break failure, is used for the TEG for line break detection. The TEG 311 comprises three TEG areas 312, 313, 314, where the respective TEG areas have four pairs of wires at the ground potential. As illustrated in the figure, the TEG area 312 has the largest line width, and the TEG area 314 has the smallest line width.

In this twenty fourth embodiment, the TEG 291 for short-circuit failure detection is positioned upstream of the TEG 311 for line break detection, as viewed from the electron beam scanning direction, because the TEG 291 is less likely to suffer from a line break failure than the TEG 311, and is therefore less susceptible to fluctuations in the semiconductor surface potential due to areas at the floating potential.

In this way, for positioning the TEG for line break detection, the TEG which is less likely to suffer from a line break failure is preferably positioned on the upstream side with respect to the electron beam scanning direction in a VC test. In addition, when there are TEG areas which differ in line width, as the TEG 291, a TEG area having a larger line width should be positioned on the upstream side because a TEG area having a larger line width is less susceptible to the line break failure.

Also, in such a TEG for line break detection, a pad structure 315 having a relatively large area is formed near a mirror symmetry axis of the TEG so as to emit many secondary electrons in response to the electron beam irradiation, and therefore so as to generate a large VC test signal. As such, only the vicinity of the pad structure 315 need be tested in order to detect whether or not a short-circuit failure is present in the TEG.

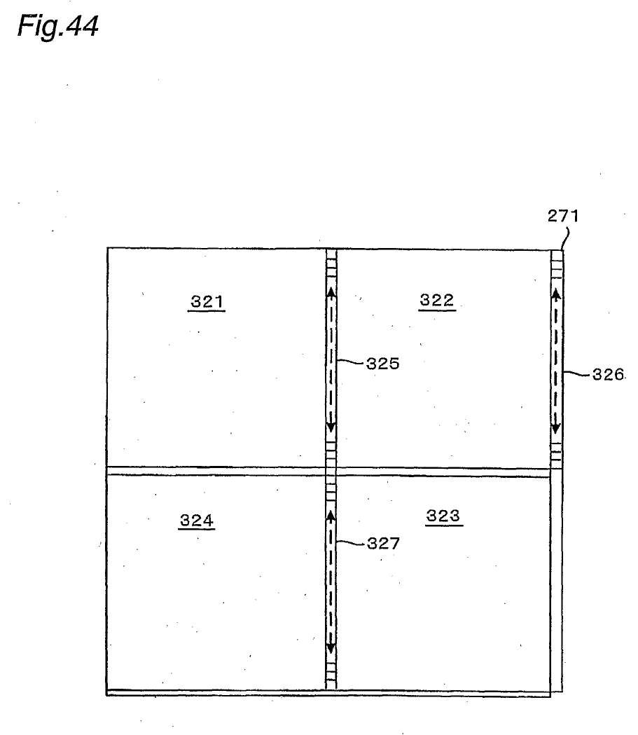

While descriptions have been so far given of a variety of TEG's according to the present invention, if a narrow scribe area is included in a peripheral zone of a product die, a TEG can be optimally disposed in the scribe area to reduce a testing time. For example, FIG. 44 shows the case where four dies 321-324 exist in a single exposure field, and a plurality of TEG's (for example, the TEG's 271 in FIG. 38) are arranged in the same direction in scribe areas 325-327 around each die. Note that the case shown in FIG. 44 is such that each die has a scribe area too small to accommodate a sufficient TEG. Accordingly, the TEG's are arranged in the same direction in all the scribe areas 325-327 within the exposure field in units of exposure fields in which the dies are placed.

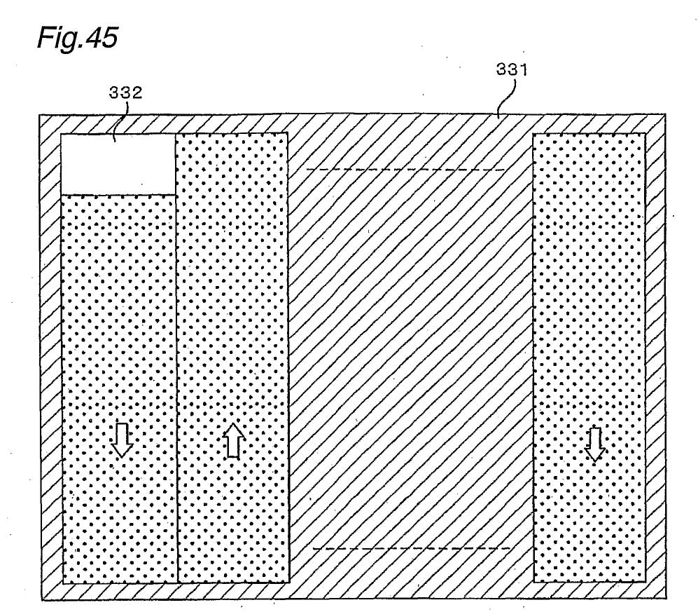

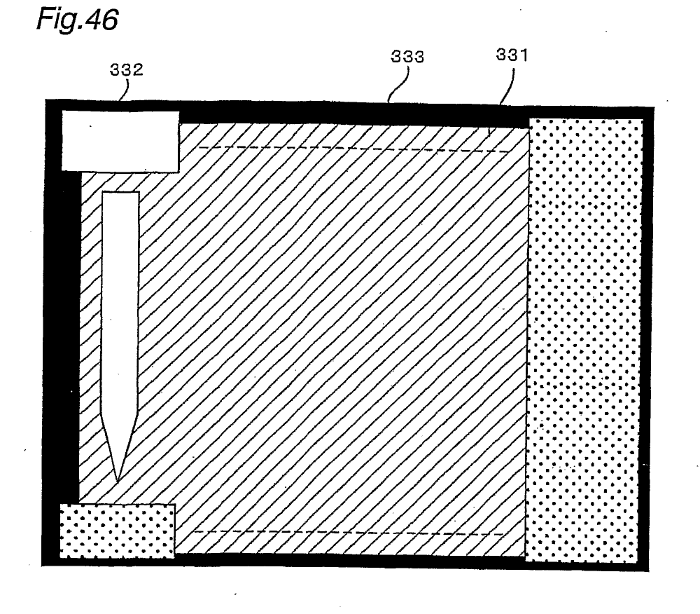

Now, a description will be given of the relationship between an area irradiated with an electron beam for scanning a TEG and the TEG. Generally, insulating films and wires at the floating potential exist around areas in which TEG's are disposed. Therefore, these insulating films and wires are disadvantageously charged if irradiated with an electron beam. Thus, as illustrated in FIG. 45, when a TEG 331 is scanned using an electron beam, or when dimensions of an area 332 irradiated with an electron beam at an instantaneous moment are appropriately selected so that the electron beam scans from one end to the other end within the TEG 331 in the column direction alternately in opposite directions, the electron beam is preferably prevented from being irradiated to areas external to the TEG 331.

However, a TEG can be limited in size and position, and an electron beam cannot be narrowed down in some cases, so that the electron beam can be likely to be irradiated to areas external to the TEG. In such an event, the periphery of the TEG 331 is preferably surrounded by a ground line 333, as illustrated in FIG. 46.

While a variety of embodiments of semiconductor devices according to the present invention have been described above, the present invention is not limited to such embodiments. As will be understood by those skilled in the art, the present invention is limited only by claims, and a variety of modifications and variations are included in the claims.

### INDUSTRIAL AVAILABILITY

As will be understood from the detailed description on embodiments of semiconductor devices according to the present invention, the present invention can efficiently detect defective connections such as electric short and line break, which occur in semiconductor LSI's, and can therefore contribute to higher efficiency of detecting defective semiconductor devices, and improved yield rate of semiconductor products. Also, in the present invention, a semiconductor device is provided with a basic wiring pattern in a specially designed shape, so that it is possible to efficiently detect failures such as a short between wires, an opened wire, and a conduction failure of vias, which occur in the basic wiring pattern, thus contributing to a higher efficiency of failure countermeasures and an improved wafer yield rate. Further, the present invention tests a plurality of TEG's which are similar in pattern shape for electric connection failures, and therefore can not only efficiently detect connection failures such as a short, a line break and the like, which occur in semiconductor devices, but also can immediately detect a deterioration in a margin and a reduction in yield rate in a manufacturing process, which can cause such failures. Consequently, it is possible to increase the efficiency of countermeasures to failures in the manufacturing process and to improve the yield rate of wafers.

1. A semiconductor device comprising a pair of row wires including a plurality of first wires arranged in a first layer at predetermined intervals in a row direction, said first wires having ends connected to second wires arranged in a second layer at predetermined intervals through vias, said first wires being at the same potential as said second wires, said semiconductor device comprising:
a first conductor connected to said first wire positioned at a first end in one row wire of said pair of row wires in the row direction, and a second conductor connected to said first wire positioned at a second end in the other row wire in the row direction.

2. A semiconductor device comprising a pair of row wires arranged in a first layer to be elongated in a row direction, and a column wire formed in a column direction so as to overlap an end of one of said pair of row wires, wherein:
in said pair of row wires,
one row wire has a first end in the row direction connected to a first conductor, and a second end connected to said column wire through a via to be set to a first potential; and
the other row wire has a second end in the row direction connected to a second conductor, and said row wire is set to a second potential.

3. A semiconductor device according to claim 1, wherein said first conductor and said second conductor have a width in the column direction equal to or more than twice and equal to or less than three times as wide as a width of said first wire in the column direction.

4. A method of testing the semiconductor according to claim 1, comprising scanning said first conductor using an electron beam, and scanning said second conductor using the electron beam to detect a change in the amount of emitted secondary electron, resulting from a difference in potential between these conductors, to detect an electric failure.

5. A testing method according to claim 4, wherein said electric failure is a short or an open.

6. A semiconductor device comprising:
a first pair of gate electrodes arranged in a first layer and elongated in a row electrode;
a second pair of gate electrodes arranged in the first layer, and elongated in the row direction;
first self-aligned contacts arranged between the gate electrodes of said first pair of gate electrodes at predetermined intervals in the row direction;
second self-aligned contacts arranged between the gate electrodes of said second pair of gate electrodes at predetermined intervals in the row direction;
a first row wire arranged in a second layer and electrically connected to said first self-aligned contact;
a second row wire arranged in the second layer, and electrically connected to said second self-aligned contact;
means arranged in the second layer at a first end in the row direction for setting said first row wire and said second row wire to a first potential;
a first conductor arranged in the second layer, and connected to said first pair of gate electrodes at a second end in the row direction; and
a second conductor arranged in the second layer, and connected to said second pair of gate electrodes at the second end in the row direction,
wherein said first conductor and said second conductor are set to a second potential different from the first potential.

7. A semiconductor device according to claim 6, wherein said first conductor and said second conductor have a width in the column direction corresponding to said first pair of gate electrodes and said second pair of gate electrodes.

8. A semiconductor device according to claim 6, wherein said first layer comprises an active area which has a diffusion layer connected to each of said first self-aligned contact and said second self-aligned contact.

9. A semiconductor device comprising:
a first interdigital gate electrode arranged in a first layer and elongated in a row direction;
a second interdigital gate electrode arranged in the first layer, and elongated in the row direction;
a first self-aligned contact arranged between digits of said first gate electrode;
a second self-aligned contact arranged between digits of said second gate electrode;
a first row wire arranged in a second layer, and electrically connected to said first self-aligned contact;
a second row electrode arranged in the second layer, and electrically connected to said second self-aligned contact;
means arranged in the second layer at a first end in the row direction for setting said first row wire and said second row wire to a first potential;
a first conductor arranged in the second layer at a second end in the row electrode, and electrically connected to said first row wire; and
a second conductor arranged in the second layer at the second end, and electrically connected to said second row wire,
wherein said first conductor and said second conductor are set to a second potential different from the first potential.

10. A semiconductor device according to claim 9, wherein said first conductor and said second conductor have a width in the column direction corresponding to said first gate electrode and said second gate electrode.

11. A semiconductor device according to claim 9, wherein said first layer comprises a linear or intermittent active area in the row direction having a diffusion layer connected to each of said first self-aligned contact and said second self-aligned contact.

12. A semiconductor device comprising:
a first pair of gate electrodes arranged in a first layer, and elongated in a row direction;
a second pair of gate electrodes arranged in the first layer, and elongated in the row direction;
a series of first bit contacts arranged between said first pair of gate electrodes at predetermined intervals in the row direction;
a series of second bit contacts arranged between said second part of gate electrodes at predetermined intervals in the row direction;
a series of first active areas formed in the first layer, and having, on a surface, a diffusion layer connected to two adjacent bit contacts of said series of first bit contacts;
a series of second active areas formed in the first layer, and having, on a surface, a diffusion layer connected to two adjacent bit contacts of said series of second bit contacts;
a series of first wires for electrically connecting two adjacent bit contacts of said series of first bit contacts;
a series of second wires for electrically connecting between two adjacent bit contacts of said series of second bit contacts;
a first conductor electrically connected to a bit contact positioned at a first end in the row direction of said series of first bit contacts;
a second conductor electrically connected to a bit contact positioned at a first end in the row direction of said series of second bit contacts;
a third conductor electrically connected to said second pair of gate electrodes at the second ends of said first pair of gate electrodes;
a fourth conductor electrically connected to said second pair of gate electrodes at the second ends of said second pair of gate electrodes in the row direction; and
means arranged in the second layer for setting said series of first wires, said series of second wires, said first conductor, and said second conductor to a first potential,
wherein said third conductor and said fourth conductor are set to a second potential different from the first potential.

13. A semiconductor device according to claim 12, wherein said first conductor, said second conductor, said third conductor, and said fourth conductor have a width in the column direction corresponding to said first pair of gate electrodes and said second pair of gate electrodes.

14. A method of testing the semiconductor device according to claim 6, comprising scanning said first conductor and said second conductor using an electron beam, and detecting a change in the amount of emitted second electrons, resulting from a difference in potential on these conductors, to detect an electric anomaly.

15. A semiconductor device comprising a basic wiring pattern including:
a first inverted C-shaped wire having a pair of parallel interdigital conductors; and
a second inverted C-shaped wire having a pair of parallel interdigital conductors and arranged interdigitally with respect to said first wire,
wherein said first wire and said second wire are set to electrically different potentials such that a short can be detected between said wires.

16. A semiconductor device comprising a basic wiring pattern including:
a first inverted C-shaped wire having parallel interdigital conductors; and
a second linear wire arranged between said parallel interdigital conductors,
wherein said first wire and said second wire are set to electrically different potentials, such that a short can be detected between said wires.

17. A semiconductor device comprising a basic wiring pattern including:
a first interdigital wire having a plurality of parallel interdigital conductors; and
a second wire having a plurality of parallel interdigital conductor, and interdigitally arranged with respect to said first wire,
wherein said first wire and said second wire are set to electrically different potentials, such that a short can be detected between said wires.

18. A semiconductor device according to claim 15, wherein said first wire is electrically grounded, and said second wire is at a floating potential.

19. A semiconductor device comprising a basic wiring pattern including an inverted C-shaped wire having parallel interdigital conductors, wherein a predetermined potential is applied to an end of one of said interdigital conductors, such that an opened wire can be detected.

20. A semiconductor device comprising a basic wiring pattern including a zig-zag shaped wire, wherein said wire is set to a predetermined potential, such that an opened wire can be detected.

21. A semiconductor device comprising a basic wiring pattern including:
a first zig-zag wire having a plurality of parallel conductors; and
a second interdigital wire interdigitally arranged with respect to said first wire, said second wire having interdigital conductors positioned between opposing conductors of said first wire,
wherein said first wire and said second wire are set to electrically different potentials, such that a short between said wires and an opened wire can be detected.

22. A semiconductor device comprising a basic wiring pattern including:
a first interdigital wire having a plurality of parallel interdigital conductors;
a second zig-zag wire having a plurality of parallel conductors, wherein at least a pair of said conductors are positioned between opposing interdigital conductors of said first wire; and
a third interdigital wire having a plurality of parallel interdigital conductors extending in a direction opposite to the interdigital conductors of said first wire, and positioned between the opposing conductors of said second wire,
wherein said second wire is set to a predetermined potential, and said first wire and said third wire are set to a potential different from the predetermined potential, such that a short between said wires, and an opened wire can be detected.

23. A semiconductor device comprising a basic wiring pattern including:
a first interdigital wire having a plurality of parallel interdigital conductors;
a second wire for connecting at least two adjacent conductors of the plurality of linear conductors arranged alternately with said interdigital conductors,
wherein said first wire is set to a predetermined potential, and said second wire is set to a potential different from the predetermined potential, such that a short can be detected between said wires.

24. A semiconductor device comprising a basic wiring pattern including:
a first zig-zag wire having a plurality of parallel conductors;
a second conductor having a plurality of inverted C-shaped conductors, wherein said respective inverted C-shaped conductors area arranged to sandwich a pair of said opposing conductors of said first wire from both sides with respect to a lengthwise direction of said first wire,
wherein said first wire is set to a predetermined potential, and said second wire is set to a potential different from the predetermined potential, such that a short between said wires and an opened wire can be detected.

25. A semiconductor device comprising a basic wiring pattern having one or more via chain including two adjacent conductors formed in a first layer, opposing ends interconnected through a contact and a conductor formed in a second layer, wherein said via chain is set to a predetermined potential, such that a conduction failure of a via can be detected.

26. A semiconductor device according to claim 25, comprising a basic wiring pattern which has said via chains arranged to form a zig-zag line.

27. A semiconductor device according to claim 26, wherein a plurality of said via chains are arranged in a line, and at least one reference row is disposed adjacent to said wiring pattern.

28. A semiconductor device according to claim 15, wherein said basic wiring pattern has a wiring pattern arranged in n rows and m columns.

29. A method of testing a semiconductor device according to any claim 15, wherein a minimum pixel size of a tester for use in testing said semiconductor device is set to a wiring pitch.

30. A method of testing a semiconductor device, wherein a maximum pixel size for a tester for use in testing the semiconductor device according to claim 15 is set to the size of a basic wiring pattern in a scanning direction of a electron beam for the test, or to the size of the same pattern which appears in the basic wiring pattern in the scanning direction.

31. A semiconductor device comprising a group of TEG's including two or more TEG's each having a wire at a ground potential and a wire at a floating potential, wherein:
said wires have the same line width and spacing in each of said TEG's, and one of the line width and spacing of said wires is different among different ones of said TEG's.

32. A semiconductor device comprising a group of TEG's including two or more TEG's each having at least two wires at a predetermined potential, wherein:
said wires have the same line width and spacing in each of said TEG's, and one of the line width and spacing of said wires is different among different ones of said TEG's.

33. A semiconductor device having a first layer formed on a first side of an insulating layer, and a second layer formed on a second side opposite to the first side, said semiconductor device comprising:
a group of TEG's having two or more TEG's, each including:
a first row wire having a plurality of wires formed in said first layer and arranged at predetermined intervals in a row direction;
a second row wire having a plurality of wires formed in said second layer so as to overlap said first row wire and include adjacent ends of said plurality of wires; and
conductors such as vias and a contact for electrically connecting the wires in said first row wire to the wires in said second row wire,
wherein said conductors are different in diameter or interval among different TEG's.

34. A method of testing the semiconductor device according to claim 31, comprising:
irradiating each of said TEG's with an electron beam to emit secondary electrons from said TEG's, and detecting the presence or absence of a wire failure site in said TEG's based on the amount of the emitted secondary electrons in accordance with a voltage contrast method.

35. A testing method according to claim 34, further comprising the step of previously storing a wiring pitch of each of said TEG's, or automatically detecting a wiring pitch of each of said TEG's, wherein wire failure sites are continuously detected using the previously stored wiring pitch or the automatically detected wiring pitch.

36. A testing method according to claim 34, comprising:
testing a plurality of groups of said TEG's on a wafer, and finding a relationship between design dimensions and a yield rate of each TEG for each of said groups of TEG's.

37. A testing method according to claim 36, comprising:
determining that said semiconductor device is defective when said yield rate is smaller than a predetermined value.

38. A testing method according to claim 36, comprising:
selecting a representative TEG from said group of TEG's, and measuring the yield rate for said representative TEG.

39. A testing method according to claim 31, wherein:
each dimension of said TEG has a value corresponding to the sum of or the difference between a design dimension and an allowable margin.

40. A semiconductor device comprising a wiring pattern including at least one TEG, said TEG comprising a plurality of wires arranged symmetrically to and parallel with an axis such that their ends oppose each other, wherein the other end of every other wire is grounded, and the remaining wires are at a floating potential in said plurality of wires.

41. A semiconductor device comprising a wiring pattern including at least one TEG, said TEG having a plurality of wires arranged symmetrically to and parallel with an axis such that their ends oppose each other, wherein the other ends of said plurality of wires are connected to a ground electrode.

42. A semiconductor device according to claim 41, wherein said plurality of wires are arranged in a first wiring layer, said ground electrode is arranged in a second wiring layer different from said first wiring layer, and said plurality of wires and said ground electrode are connected through vias.

43. A semiconductor device according to claim 40 further comprising a wire disposed in an area having a predetermined width centered at said axis, and set at a the ground potential or the floating potential.

44. A semiconductor device according to claim 40, comprising a wiring pattern which has a plurality of said TEG's arranged in a predetermined direction.

45. A semiconductor device according to claim 44, wherein a multiple of two or a multiple of two's power of said TEG's are arranged in the predetermined direction.

46. A semiconductor device according to claim 44, wherein:
a plurality of said TEG's are different in design parameters such as a line width, a distance between lines, and the like from one another, and
a plurality of said TEG's are arranged in an order in which line break failures occur less frequently with respect to an electron beam scanning direction during a test in accordance with voltage contrast.

47. A semiconductor device according to claim 46, wherein said plurality of TEG's are arranged across a plurality of wiring layers, wherein TEG's arranged in the same wiring layer are continuously arranged with respect to the electron beam scanning direction during the test in accordance with the voltage contrast.

48. A semiconductor device according to claim 40, wherein TEG's which less frequently suffer from line break failure are arranged on one side, or on the other side, or on both sides of said TEG's arranged in the same wiring layer, with respect to the electron beam scanning direction during the test in accordance with the voltage contrast.

49. A semiconductor device according to claim 40, wherein when said TEG's arranged in the same wiring layer include a TEG for short-circuit failure detection and a TEG for line break failure detection, said TEG for short-circuit failure detection is arranged on an upstream side with respect to the electron beam scanning direction during the test in accordance with the voltage contrast.

50. A semiconductor device according to claim 40, wherein said TEG is disposed in a scribe area in a direction parallel or perpendicular to said axis within a field exposed to said electron beam.

51. A semiconductor device according to claim 40, further comprising a ground wire surrounding the periphery of said wiring pattern.

52. A semiconductor device according to claim 40, wherein a testing method comprises irradiating an electron beam to an area having a predetermined width and including ends of said plurality of wires opposite to said axis, and detecting a defective locations based on a voltage contrast signal corresponding to the amount of secondary electrons emitted from said area.

53. A semiconductor device according to claim 52, wherein a testing method comprises scanning said semiconductor device using said electron beam in a direction parallel with said axis while sequentially shifting the position, and continuously detecting defective locations based on the voltage contrast signal corresponding to the amount of secondary electrons emitted in response to the irradiation of the electron beam.

54. A testing method according to claim 52, comprising simultaneously irradiating the electron beam to a plurality of areas positioned at predetermined intervals in a direction perpendicular to said axis to continuously detect defective locations.

55. A testing method according to claim 52, wherein the width of said TEG in a direction perpendicular to said axis is divided by the width of said electron beam in a direction perpendicular to said axis to result in a multiple of two or a two's power.

56. A testing method according to claim 52, comprising:
scanning said semiconductor device in the direction perpendicular to said axis using said electron beam having a first width to detect said TEG in which a failure exists, and
scanning said TEG in which a failure has been detected in the direction perpendicular to said axis using said electron beam having a second width smaller than said first width.

57. A testing method according to claim 56, wherein:
the width of said TEG in the direction perpendicular to said axis is divided by said first width to result in a multiple of two or a two's power, and
said first width is divided by said second width to result in an integer, a multiple of two, or a two's power.

58. A testing method according to claim 52, comprising:
performing the scan using the electron beam without scanning outside of an area in which said wiring pattern is formed.
